(19) United States
(12) Patent Application Publication
(10) Pub. No.: US 2026/0221981 A1
(43) Pub. Date: Jul. 30, 2026

(54) METHODS AND APPARATUS TO NOTCH FILTER USING PARALLEL FILTER CIRCUITRY

(71) Applicant: Texas Instruments Incorporated, Dallas, TX (US)

(72) Inventors: Ralph Georg Oberhuber, Oro Valley, AZ (US); Shawn Xianggang Yu, Tuscon, AZ (US); Joachim Erwin Wuerker, Tucson, AZ (US)

(21) Appl. No.: 19/041,466

(22) Filed: Jan. 30, 2025

(51) Int. Cl. H03M 1/06; H03M 1/10; H03M 1/12

(52) U.S. Cl. CPC H03M 1/0626; H03M 1/1023; H03M 1/1245

(57) ABSTRACT

An example apparatus includes: decimation filter circuitry having an output; multiplexer circuitry having an input, a first output and a second output, the input of the multiplexer circuitry coupled to the output of the decimation filter circuitry; first delay circuitry having an input and an output, the input of the first delay circuitry coupled to the first output of the multiplexer circuitry; first filter circuitry having an input coupled to the output of the first delay circuitry; second delay circuitry having an input and an output, the input of the second delay circuitry coupled to the second output of the multiplexer circuitry; and second filter circuitry having an input coupled to the output of the second delay circuitry.

### TECHNICAL FIELD

This description relates generally to filtering and, more particularly, to methods and apparatus to notch filter using parallel filter circuitry.

### BACKGROUND

In signal processing systems, filter circuitry reduces processing complexity by reducing contributions from signals outside of a range of frequencies. Some different types of filters include high-pass filters, low-pass filters, band-pass filters, and notch filters. High-pass filter circuitry attenuates signals having a frequency less than a cutoff frequency. Low-pass filter circuitry attenuates signals having a frequency greater than a cutoff frequency. Band pass filter circuitry attenuates signals having a frequency less than a first cutoff frequency or greater than a second cutoff frequency. Notch filter circuitry attenuates signals of a specific frequency. Notch filter circuitry allows a system to suppress signals having a frequency inside an operating bandwidth of the system.

### SUMMARY

For methods and apparatus to notch filter using parallel filter circuitry, an example apparatus includes decimation filter circuitry having an output; multiplexer circuitry having an input, a first output and a second output, the input of the multiplexer circuitry coupled to the output of the decimation filter circuitry; first delay circuitry having an input and an output, the input of the first delay circuitry coupled to the first output of the multiplexer circuitry; first filter circuitry having an input coupled to the output of the first delay circuitry; second delay circuitry having an input and an output, the input of the second delay circuitry coupled to the second output of the multiplexer circuitry; and second filter circuitry having an input coupled to the output of the second delay circuitry. Other examples are described.

For methods and apparatus to notch filter using parallel filter circuitry, an example apparatus includes an analog to digital converter (ADC) having an output; decimation filter circuitry having an input and an output, the input of the decimation filter circuitry coupled to the output of the ADC; multiplexer circuitry having an input, a first output, and a second output, the input of the multiplexer circuitry coupled to the output of the decimation filter circuitry; first filter circuitry having an input coupled to the first output of the multiplexer circuitry; and second filter circuitry having an input coupled to the second output of the multiplexer circuitry. Other examples are described.

For methods and apparatus to notch filter using parallel filter circuitry, an example apparatus includes multiplexer circuitry having a first output and a second output; first delay circuitry having an input and an output, the input of the first delay circuitry coupled to the first output of the multiplexer circuitry, the first delay circuitry configured to delay signals by a duration, the duration based on a number of filter circuitry, a notch frequency, and an oversampling rate; second delay circuitry having an input and an output, the input of the second delay circuitry coupled to the second output of the multiplexer circuitry, the second delay circuitry configured to delay signals by the duration; first filter circuitry having an input coupled to the output of the first delay circuitry; and second filter circuitry having an input coupled to the output of the second delay circuitry. Other examples are described.

### BRIEF DESCRIPTION OF THE DRAWINGS

FIG. 1 is a block diagram of example delta-sigma analog-to-digital converter (ADC) circuitry including notch filter circuitry.

FIG. 2 is a block diagram of an example of the notch filter circuitry of FIG. 1 including example controller circuitry and a plurality of example filter circuitry coupled in parallel.

FIG. 3 is a block diagram of an example of the filter circuitry of FIG. 2.

FIG. 4 is a flowchart representative of example machine-readable instructions or example operations that may be at least one of executed, instantiated, or performed using an example implementation of the filter circuitry of FIGS. 2 and 3 or more generally the notch filter circuitry of FIGS. 1 and 2.

FIG. 5 is a block diagram of an example implementation of the controller circuitry of FIG. 2.

FIG. 6 is a flowchart representative of example machine-readable instructions or example operations that may be at least one of executed, instantiated, or performed using an example implementation of the controller circuitry of FIGS. 2 and 5 or more generally the notch filter circuitry of FIGS. 1 and 2.

FIG. 7 is a timing diagram of example operations of the notch filter circuitry of FIGS. 1 and 2 to filter a notch signal at a notch frequency.

FIG. 8 is a timing diagram of example operations of the plurality of example filter circuitry of FIGS. 2 and 3 to filter the notch signal of FIG. 7 at the notch frequency.

FIG. 9 is a block diagram of an example processing platform including programmable circuitry structured to execute, instantiate, or perform the example machine-readable instructions or perform the example operations of FIGS. 4 and 6 to implement the controller circuitry of FIGS. 2 and 5 or more generally, the notch filter circuitry of FIGS. 1 and 2.

FIG. 10 is a block diagram of an example implementation of the programmable circuitry of FIG. 9.

FIG. 11 is a block diagram of another example implementation of the programmable circuitry of FIG. 9.

The drawings are not necessarily to scale. Generally, the same reference numbers in the drawing(s) and this description refer to the same or similar (functionally and/or structurally) features and/or parts. Although the drawings show regions with clean lines and boundaries, some or all of these lines and boundaries may be idealized. In reality, the boundaries or lines may be unobservable, blended or irregular.

### DETAILED DESCRIPTION

In signal processing systems, filter circuitry reduces processing complexity by reducing contributions from signals outside of a range of frequencies. Some different types of filters include high-pass filters, low-pass filters, band-pass filters, and notch filters. High-pass filter circuitry attenuates signals having a frequency less than a cutoff frequency. Low-pass filter circuitry attenuates signals having a frequency greater than a cutoff frequency. Band pass filter circuitry attenuates signals having a frequency less than a first cutoff frequency or greater than a second cutoff frequency. Notch filter circuitry attenuates signals of a specific frequency. Notch filter circuitry allows a system to suppress signals having a frequency inside an operating bandwidth of the system.

Some devices, such as analog-to-digital converters (ADCs), use notch filters to attenuate noisy signals at a certain frequency. Such a frequency is referred to as a notch frequency. In some designs, adjusting the sampling rate of the ADC structures the ADC to filter out signals at the notch frequency. In such designs, setting the sampling rate to a multiple of the notch frequency filters signals at the notch frequency at the output of the ADC. However, for low frequency notch filtering, such notch filtering limits the sampling rate of the ADC to a fraction, of the notch frequency, such as an integer fraction. As electronics continue to advance, increasingly higher speed signal processing relies on increasingly higher speed ADCs.

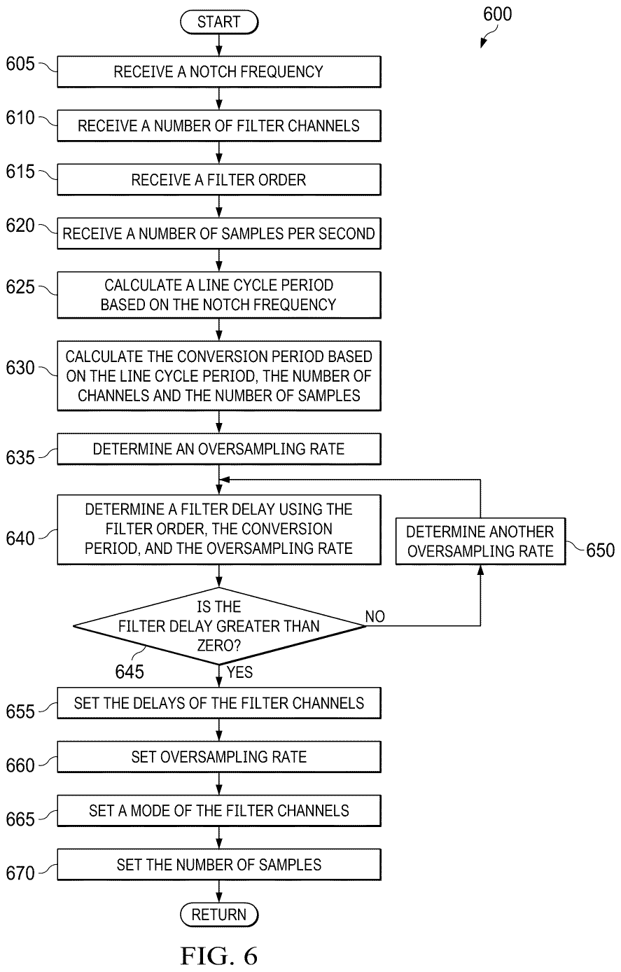

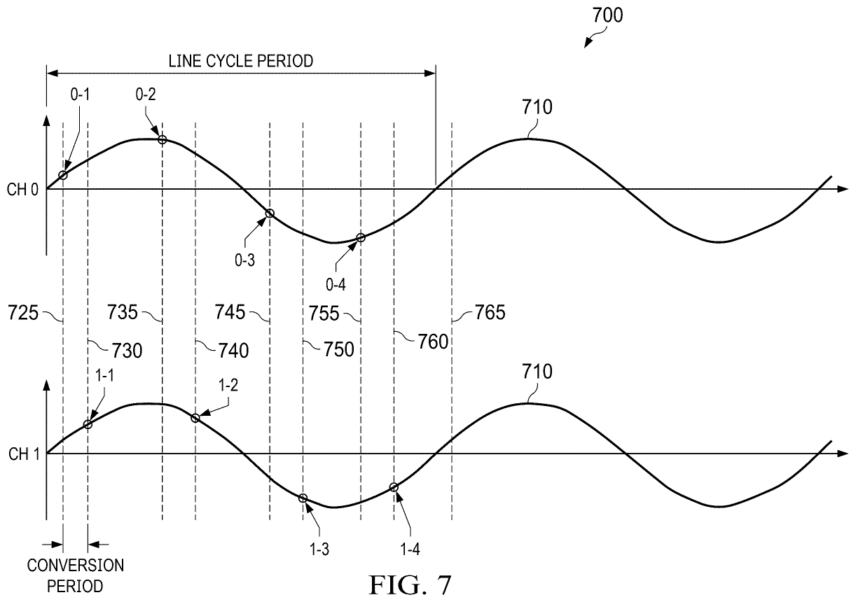

Examples described herein include methods and apparatus to notch filter using parallel filter circuitry. Some described examples include notch filter circuitry further including decimation filter circuitry, multiplexer circuitry, and a plurality of filter channels. The decimation filter circuitry receives digital input values from the ADC circuitry. The decimation filter circuitry decimates the digital input values at an oversample rate (OSR). During decimation, the decimation filter circuitry averages a number of digital input values. The number of digital values that the decimation filter circuitry averages is set by the OSR. The decimation filter circuitry provides oversamples to the multiplexer circuitry. An oversample is a single value representing the decimation of a plurality of digital values. The multiplexer circuitry provides the oversample to one of the filter channels based on a conversion period. The conversion period sequences the multiplexer circuitry to cycle between providing the oversample to each of the filter channels. The conversion period is equal to a line cycle period of the notch frequency divided by a multiplication of the number of filter channels and the number of samples being filtered per period of the notch frequency. Such a calculation is further illustrated and described in connection with FIGS. 6 and 7.

In such described examples, the filter channels include delay circuitry and filter circuitry. The delay circuitry delays oversamples from the multiplexer circuitry by a filter delay. The filter circuitry is a non-decimating moving average filter. The filter circuitry averages oversamples from the delay circuitry. In example operations, during a first conversion period, the multiplexer circuitry provides the oversamples to first delay circuitry of a first filter channel. The first delay circuitry delays providing oversamples to first filter circuitry by the filter delay. The first filter circuitry averages oversamples from subsequent conversion periods to attenuate signals at the notch frequency. After the first conversion period, during a second conversion period, the multiplexer circuitry provides the oversamples to second delay circuitry of a second filter channel. Similar to the first filter channel, during the second conversion period, the delay circuitry delays providing oversamples to second filter circuitry by the filter delay. The second filter circuitry averages oversamples from subsequent conversion periods to attenuate signals at the notch frequency. In such example operations, the multiplexer circuitry cycles through each of the filter channels using the conversion period.

Advantageously, the filter channels average amplitudes of signals at the notch frequency. Advantageously, periodically averaging signals of the notch frequency attenuates signals at the notch frequency. Advantageously, the notch filter circuitry filters a notch frequency without changing the sampling rate of the ADC.

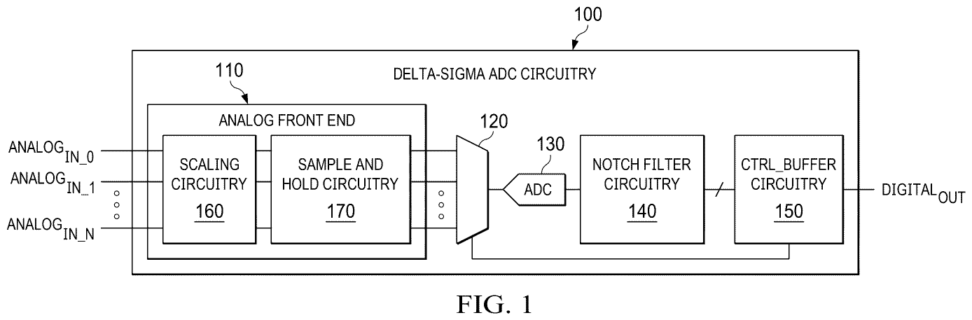

FIG. 1 is a block diagram of example delta-sigma analog-to-digital converter (ADC) circuitry 100. In the example of FIG. 1, the delta-sigma ADC circuitry 100 includes an analog front end (AFE) 110, a multiplexer circuitry 120, an ADC 130, notch filter circuitry 140, and control buffer circuitry 150. The example AFE 110 of FIG. 1 includes example scaling circuitry 160 and example sample and hold circuitry 170.

The delta-sigma ADC circuitry 100 has a first input, a second input, a third input, and an output. The first input of the delta-sigma ADC circuitry 100 is structured to be coupled to a first analog signal source, which provides a first analog signal (ANALOG_{IN_0}). The second input of the delta-sigma ADC circuitry 100 is structured to be coupled to a second analog signal source, which provides a second analog signal (ANALOG_{IN_1}). The third input of the delta-sigma ADC circuitry 100 is structured to be coupled to a third analog signal source, which provides a third analog signal (ANALOG_{IN_N}). In some examples, the delta-sigma ADC circuitry 100 may have any number of inputs coupled to any number of analog signal sources, which respectively provide any number of analog signals. However, as the number of inputs of the delta-sigma ADC circuitry 100 increase, a conversion speed or a data rate of the analog signals decreases. The output of the delta-sigma ADC circuitry 100 (DIGITAL_{OUT}) is structured to be coupled to external circuitry.

The AFE 110 has a first input, a second input, a third input, a first output, a second output, and a third output. The first, second, and third inputs of the AFE 110 are coupled to respective ones of the first, second, and third inputs of the delta-sigma ADC circuitry 100 (ANALOG_{IN_0}, ANALOG_{IN_1}, ANALOG_{IN_N}). The first, second, and third outputs of the AFE 110 are coupled to the multiplexer circuitry 120.

The multiplexer circuitry 120 has a first input, a second input, a third input, a control input, and an output. The first, second, and third inputs of the multiplexer circuitry 120 are coupled to the AFE 110. The control input of the multiplexer circuitry 120 is coupled to the control buffer circuitry 150. The output of the multiplexer circuitry 120 is coupled to the ADC 130.

The ADC 130 has an input and an output. The input of the ADC 130 is coupled to the multiplexer circuitry 120. The output of the ADC 130 is coupled to the notch filter circuitry 140.

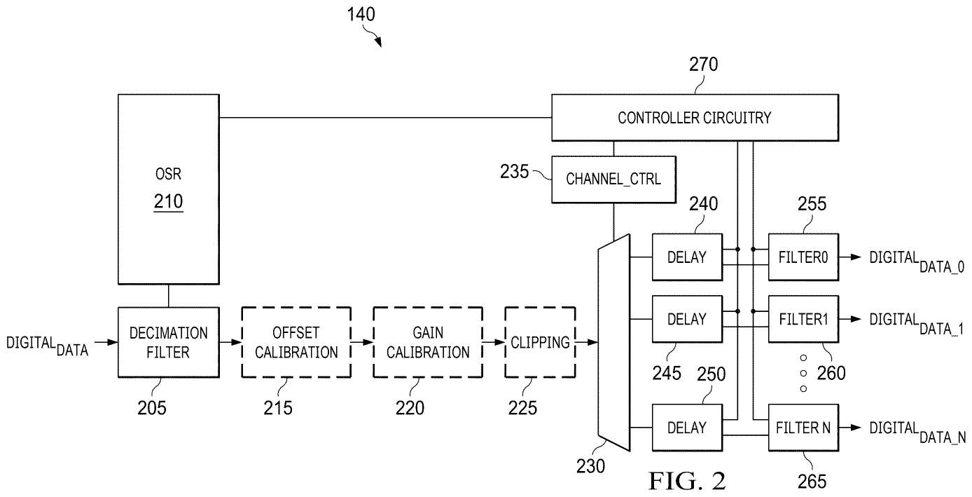

The notch filter circuitry 140 has an input and outputs. The input of the notch filter circuitry 140 is coupled to the ADC 130. The outputs of the notch filter circuitry 140 are coupled to the control buffer circuitry 150 (DIGITAL_{OUT}). An example of the notch filter circuitry 140 is further illustrated and described in connection with FIG. 2.

The control buffer circuitry 150 has inputs, a first output, and a second output. The inputs of the control buffer circuitry 150 are coupled to the notch filter circuitry 140. The first output of the control buffer circuitry 150 is coupled to the multiplexer circuitry 120. The second output of the control buffer circuitry 150 is coupled to the output of the delta-sigma ADC circuitry 100.

The scaling circuitry 160 has a first input, a second input, a third input, a first output, a second output, and a third output. The first, second, and third inputs of the scaling circuitry 160 are coupled to respective ones of the first, second, and third inputs of the delta-sigma ADC circuitry 100 (ANALOG_{IN_0}, ANALOG_{IN_1}, ANALOG_{IN_N}). The first, second, and third outputs of the scaling circuitry 160 are coupled to the sample and hold circuitry 170.

The sample and hold circuitry 170 has a first input, a second input, a third input, a first output, a second output, and a third output. The first, second, and third inputs of the sample and hold circuitry 170 are coupled to the scaling circuitry 160. The first, second, and third outputs of the sample and hold circuitry 170 are coupled to the multiplexer circuitry 120.

In example operation, the AFE 110 receives the first, second, and third analog signals (ANALOG_{IN_0}, ANALOG_{IN_1}, ANALOG_{IN_N}) from external analog signal sources. In some examples, the AFE 110 may receive any number of analog signals. The scaling circuitry 160 scales the first, second, and third analog signals by a gain. In some examples, the scaling circuitry 160 individually scales the analog signals by respective gain values. The sample and hold circuitry 170 periodically samples the first, second, and third analog signals. The sample and hold circuitry 170 provide sampled analog values to the multiplexer circuitry 120. The control buffer circuitry 150 sequences the supply of the sampled analog values to the ADC 130.

In such example operations, the ADC 130 converts the sampled analog values into sequential digital values. The ADC 130 provides the digital values to the notch filter circuitry 140. The notch filter circuitry 140 decimates and averages the digital values to filter signals of a notch frequency from the digital values. The notch filter circuitry 140 provides the filtered digital values to the control buffer circuitry 150. The control buffer circuitry 150 buffers the filtered digital values. In some examples, the control buffer circuitry 150 reconstructs the signal paths of the first, second, and third analog signals by positioning different digital outputs in different buffers. For example, the control buffer circuitry 150 can produce first, second and third digital signals respectively corresponding to one of the first, second, or third analog signals. Advantageously, the notch filter circuitry 140 filters signals at the notch frequency without reducing the sampling rate of the delta-sigma ADC circuitry 100. Example operations of the notch filter circuitry 140 are further illustrated and described in connection with FIGS. 2, 3, 4, 5, and 6.

FIG. 2 is a block diagram of an example of the notch filter circuitry 140 of FIG. 1. The example notch filter circuitry 140 of FIG. 2 includes example decimation filter circuitry 205, example oversampling ratio (OSR) circuitry 210, example offset calibration circuitry 215, example gain calibration circuitry 220, example clipping circuitry 225, example multiplexer circuitry 230, example channel control circuitry 235, first example delay circuitry 240, second example delay circuitry 245, third example delay circuitry 250, first example filter circuitry 255, second example filter circuitry 260, and third example filter circuitry 265.

The notch filter circuitry 140 has an input, a first output, a second output, and a third output. The input of the notch filter circuitry 140 (DIGITAL_{DATA}) is structured to be coupled to a digital signal source, such as the ADC 130 of FIG. 1. The first, second, and third outputs of the notch filter circuitry 140 (DIGITAL_{DATA_0}, DIGITAL_{DATA_1}, DIGITAL_{DATA_N}) are structured to be coupled to the control buffer circuitry 150 of FIG. 1.

The decimation filter circuitry 205 has a first input, a second input, and an output. The first input of the decimation filter circuitry 205 is coupled to the input of the notch filter circuitry 140 (DIGITAL_{DATA}). The second input of the decimation filter circuitry 205 is coupled to the OSR circuitry 210. The output of the decimation filter circuitry 205 is coupled to the offset calibration circuitry 215.

The OSR circuitry 210 has an output coupled to the decimation filter circuitry 205. In some examples, the OSR circuitry 210 is memory circuitry structured to store an oversampling rate, such as a register or a portion of a relatively larger memory structure. In such examples, the OSR circuitry 210 is programmable by the controller circuitry 270. Alternatively, the OSR circuitry 210 may be illustrated or described as part of the decimation filter circuitry 205 or the controller circuitry 270.

The offset calibration circuitry 215 has an input and an output. The input of the offset calibration circuitry 215 is coupled to the decimation filter circuitry 205. The output of the offset calibration circuitry 215 is coupled to the gain calibration circuitry 220.

The gain calibration circuitry 220 has an input and an output. The input of the gain calibration circuitry 220 is coupled to the offset calibration circuitry 215. The output of the gain calibration circuitry 220 is coupled to the clipping circuitry 225.

The clipping circuitry 225 has an input and an output. The input of the clipping circuitry 225 is coupled to the gain calibration circuitry 220. The output of the clipping circuitry 225 is coupled to the multiplexer circuitry 230.

The multiplexer circuitry 230 has a data input, a control input, a first output, a second output, and a third output. The data input of the multiplexer circuitry 230 is coupled to the clipping circuitry 225. In some examples, as illustrated by the dashed outline, the first input of the multiplexer circuitry 230 is directly coupled to the decimation filter circuitry 205. The control input of the multiplexer circuitry 230 is coupled to the channel control circuitry 235. The first output of the multiplexer circuitry 230 is coupled to the delay circuitry 240. The second output of the multiplexer circuitry 230 is coupled to the delay circuitry 245. The third output of the multiplexer circuitry 230 is coupled to the delay circuitry 250. The multiplexer circuitry 230 may also be referred to as a demultiplexer.

The channel control circuitry 235 has an input and an output. The input of the channel control circuitry 235 is coupled to the controller circuitry 270. The output of the channel control circuitry 235 is coupled to the multiplexer circuitry 230. In some examples, the channel control circuitry 235 is memory circuitry structured to store a control value, such as a register or a portion of a relatively larger memory structure. In such examples, the channel control circuitry 235 is programmable by the controller circuitry 270. Alternatively, the channel control circuitry 235 may be illustrated or described as part of the multiplexer circuitry 230 or the controller circuitry 270.

The delay circuitry 240 has a data input, a control input, and an output. The data input of the delay circuitry 240 is coupled to the multiplexer circuitry 230. The control input of the delay circuitry 240 is coupled to the delay circuitry 245, 250 and the controller circuitry 270. The output of the delay circuitry 240 is coupled to the filter circuitry 255.

The delay circuitry 245 has a data input, a control input, and an output. The data input of the delay circuitry 245 is coupled to the multiplexer circuitry 230. The control input of the delay circuitry 245 is coupled to the delay circuitry 240, 250 and the controller circuitry 270. The output of the delay circuitry 245 is coupled to the filter circuitry 260.

The delay circuitry 250 has a data input, a control input, and an output. The data input of the delay circuitry 250 is coupled to the multiplexer circuitry 230. The control input of the delay circuitry 250 is coupled to the delay circuitry 240, 245 and the controller circuitry 270. The output of the delay circuitry 250 is coupled to the filter circuitry 265.

The filter circuitry 255 has a data input, a control input, and an output. The data input of the filter circuitry 255 is coupled to the delay circuitry 240. The control input of the filter circuitry 255 is coupled to the filter circuitry 260, 265 and the controller circuitry 270. The output of the filter circuitry 255 is coupled to the first output of the notch filter circuitry 140 (DIGITAL_{DATA_0}).

The filter circuitry 260 has a data input, a control input, and an output. The data input of the filter circuitry 260 is coupled to the delay circuitry 245. The control input of the filter circuitry 260 is coupled to the filter circuitry 255, 265 and the controller circuitry 270. The output of the filter circuitry 260 is coupled to the second output of the notch filter circuitry 140 (DIGITAL_{DATA_1}).

The filter circuitry 265 has a data input, a control input, and an output. The data input of the filter circuitry 265 is coupled to the delay circuitry 250. The control input of the filter circuitry 265 is coupled to the filter circuitry 255, 260 and the controller circuitry 270. The output of the filter circuitry 265 is coupled to the third output of the notch filter circuitry 140 (DIGITAL_{DATA_N}).

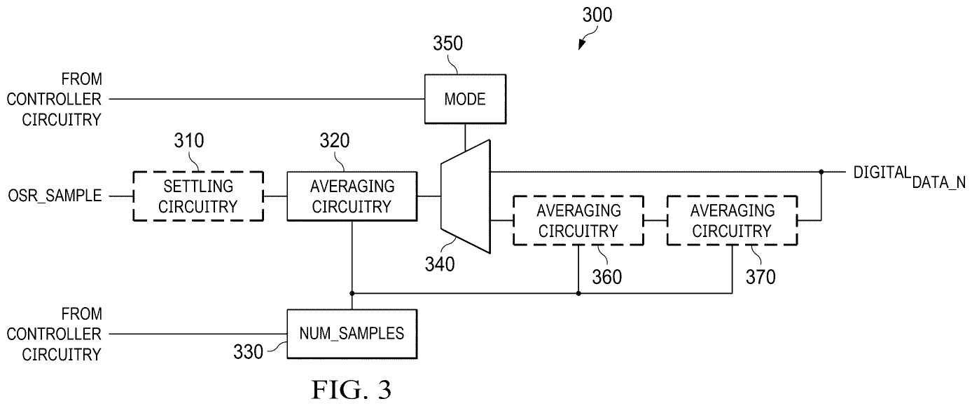

FIG. 3 is a block diagram of example of filter circuitry 300, which is an example implementation of the filter circuitry 255, 260, 265 of FIG. 2. The example filter circuitry 300 of FIG. 3 includes example settling circuitry 310, first example averaging circuitry 320, example number of samples circuitry 330, example multiplexer circuitry 340, example mode circuitry 350, second example averaging circuitry 360, and third example averaging circuitry 370.

The filter circuitry 300 has a data input, a first control input, a second control input, and an output. The data input of the filter circuitry 300 (OSR_SAMPLE) is structured to be coupled to delay circuitry, such as the delay circuitry 240, 245, 250 of FIG. 2. The first and second control inputs of the filter circuitry 300 (MODE, NUM_SAMPLES) are structured to be coupled to controller circuitry, such as the controller circuitry 270 of FIG. 2. The output of the filter circuitry 300 (DIGITAL_{DATA_N}) is structured to be coupled to buffer circuitry, such as the control buffer circuitry 150 of FIG. 1.

The settling circuitry 310 has an input and an output. The input of the settling circuitry 310 is coupled to the data input of the filter circuitry 300 (OSR_SAMPLE). The output of the settling circuitry 310 is coupled to the averaging circuitry 320.

The averaging circuitry 320 has a data input, a control input, and an output. The data input of the averaging circuitry 320 is coupled to the settling circuitry 310. The control input of the averaging circuitry 320 is coupled to the number of sample circuitry 330 and the averaging circuitry 360, 370. The output of the averaging circuitry 320 is coupled to the multiplexer circuitry 340.

The number of samples circuitry 330 has an input and an output. The input of the number of samples circuitry 330 is coupled to the first control input of the filter circuitry 300. The output of the number of samples circuitry 330 is coupled to the averaging circuitry 320, 360, 370.

The multiplexer circuitry 340 has a data input, a control input, a first output, and a second output. The data input of the multiplexer circuitry 340 is coupled to the averaging circuitry 320. The control input of the multiplexer circuitry 340 is coupled to the mode circuitry 350. The first output of the multiplexer circuitry 340 is coupled to the averaging circuitry 370 and the output of the filter circuitry 300 (DIGITAL_{DATA_N}). The second output of the multiplexer circuitry 340 is coupled to the averaging circuitry 360.

The mode circuitry 350 has an input and an output. The input of the mode circuitry 350 is coupled to the second control input of the filter circuitry 300. The output of the mode circuitry 350 is coupled to the multiplexer circuitry 340.

The averaging circuitry 360 has a data input, a control input, and an output. The data input of the averaging circuitry 360 is coupled to the multiplexer circuitry 340. The control input of the averaging circuitry 360 is coupled to the averaging circuitry 320, 370 and the number of samples circuitry 330. The output of the averaging circuitry 360 is coupled to the averaging circuitry 370.

The averaging circuitry 370 has a data input, a control input, and an output. The data input of the averaging circuitry 370 is coupled to the averaging circuitry 360. The control input of the averaging circuitry 370 is coupled to the averaging circuitry 320, 360 and the number of samples circuitry 330. The output of the averaging circuitry 370 is coupled to the multiplexer circuitry 340 and the output of the filter circuitry 300 (DIGITAL_{DATA_N}).

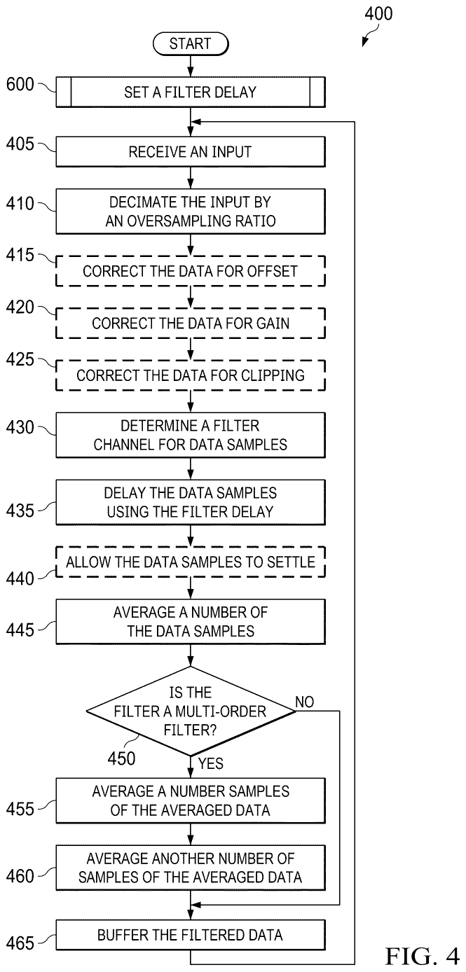

FIG. 4 is a flowchart representative of example machine-readable instructions or example operations 400 that may be at least one of executed, instantiated, or performed using an example implementation of the filter circuitry 255, 260, 265 of FIGS. 2 and 3 or more generally the notch filter circuitry 140 of FIGS. 1 and 2. The example operations 400 of FIG. 4 begin with example operation 600 of FIG. 6, at which the controller circuitry 270 of FIG. 2 sets a filter delay. In example operations, as further illustrated and described in connection with FIG. 6, the controller circuitry 270 sets the OSR circuitry 210 of FIG. 2, the channel control circuitry 235 of FIG. 2, the delay circuitry 240, 245, 250 of FIG. 2, the number of samples circuitry 330 of FIG. 3, and the mode circuitry 350 of FIG. 3. In some examples, one or more portions of the controller circuitry 270 are integrated on-chip. In other examples, one or more portions of the controller circuitry 270 may be implemented off-chip. In such examples, another device implements the one or more portions of the controller circuitry 270 to execute the operations 600 of FIG. 6 prior to run time, such as during calibration or at power-up. Control proceeds to Block 405.

The notch filter circuitry 140 receives an input. (Block 405). In example operations, the ADC 130 of FIG. 1 provides digital values responsive to converting analog values of an analog signal. In such example operations, the notch filter circuitry 140 is structured to attenuate signals at a notch frequency from the digital values.

The decimation filter circuitry 205 of FIG. 2 decimates the input by an oversampling ratio. (Block 410). In example operations, the OSR circuitry 210 provides an oversampling rate to the decimation filter circuitry 205. The oversampling rate represents a number of subsequent digital values the decimation filter circuitry 205 filters. In such example operations, the decimation filter circuitry 205 averages the number of subsequent digital value to produce an oversample (OSR_SAMPLE). For example, the decimation filter circuitry 205 divides the sum of one-hundred and twenty-eight sequential digital values by one-hundred and twenty-eight to produce a first oversample responsive to an OSR of one-hundred and twenty-eight. In such examples, the decimation filter circuitry 205 divides the sum of subsequent one-hundred and twenty-eight sequential digital values by one-hundred and twenty-eight to produce a second oversample. Advantageously, the decimation filter circuitry 205 filters relatively high-frequencies responsive to averaging a plurality of digital values.

In some examples, as illustrated by the dashed outline, the offset calibration circuitry 215 of FIG. 2 corrects the data for offset. (Block 415). In example operations, the offset calibration circuitry 215 removes DC offset from the oversamples. Advantageously, the offset calibration circuitry 215 reduces averaging error resulting from DC offset.

In some examples, as illustrated by the dashed outline, the gain calibration circuitry 220 of FIG. 2 corrects the data for gain. (Block 420). In example operations, the gain calibration circuitry 220 amplifies the oversampled values. In such example operations, the gain calibration circuitry 220 accounts for the gain of the notch filter circuitry 140. Also, in some examples, the gain calibration circuitry 220 scales the oversampled values to account for gain errors of the AFE 110 or external components.

In some examples, as illustrated by the dashed outline, the clipping circuitry 225 of FIG. 2 corrects the data for clipping. (Block 425). In example operations, the clipping circuitry 225 determines if magnitudes of oversampled values are between maximum and minimum values. In such example operations, the clipping circuitry 225 sets the magnitude of oversampled values to the maximum or minimum value responsive to a determination that the oversampled value is not between the maximum and minimum values. Advantageously, the gain calibration circuitry 220 and the clipping circuitry 225 improve the likelihood of oversamples being within a range of values.

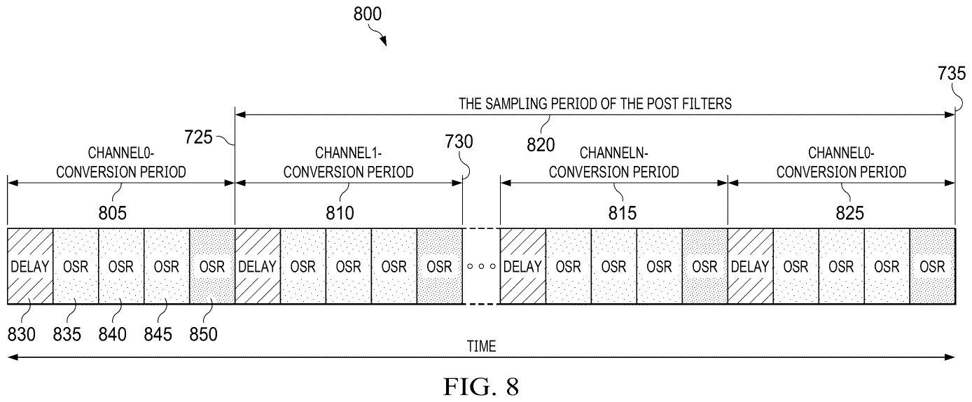

The multiplexer circuitry 230 of FIG. 2 determines a filter channel for the data samples. (Block 430). In example operations, the multiplexer circuitry 230 provides the oversample to one of the delay circuitry 240, 245, 250 responsive to the channel control circuitry 235 of FIG. 2. In such example operations, the multiplexer circuitry 230 cycles through each of the delay circuitry 240, 245, 250 based on a conversion period. The conversion period represents a division of a period of the notch frequency that the filter circuitry 255, 260, 265 sample. For example, as further illustrated in FIG. 8, the channel control circuitry 235 changes the supply of the oversample after each conversion period. The multiplexer circuitry 230 cycles supplying oversamples to each of the delay circuitry 240, 245, 250.

At least one of the delay circuitry 240, 245, 250 delays the data samples using the filter delay. (Block 435). In example operations, the delay circuitry 240, 245, 250 delay providing oversamples to the filter circuitry 255, 260, 265 by a filter delay. The filter delay accounts for a difference in time between the conversion period of the filter circuitry 255, 260, 265 and timing of the oversamples. Example sequencing of the filter delay, oversamples, and conversion periods are further illustrated and described in connection with FIGS. 6, 7, and 8.

In some examples, as illustrated by the dashed outline, the settling circuitry 310 of FIG. 3 allows data samples to settle. (Block 440). In example operations, the settling circuitry 310 discards (e.g., removes, ignores, etc.) one or more oversamples prior to providing a settled oversample. In some examples, switching components of the multiplexer circuitry 230 introduce noise to the oversamples. In such examples, the settling circuitry 310 filters noise resulting from switching of the multiplexer circuitry 230 responsive to ignoring initial oversamples of a conversion period. Advantageously, the settling circuitry 310 allows oversamples to settle prior to further filtering.

The averaging circuitry 320 of FIG. 3 averages a number of data samples. (Block 445). In example operations, the number of samples circuitry 330 of FIG. 3 structures the averaging circuitry 320 to average a number of samples. In such example operations, the averaging circuitry 320 averages the number of samples across a plurality of sampling periods. The sampling period of the notch filter circuitry 140 is a duration of the cycling of the supply of oversample to each of the delay circuitry 240, 245, 250. For example, if the notch filter circuitry 140 cycles between eight instances of the filter circuitry 300, the sampling period is eight conversion periods. Unlike the decimation filter circuitry 205, the averaging circuitry 320 provides a moving average of the oversamples from previous sampling periods. For example, the averaging circuitry 320 averages a first, second, third, and fourth oversample to produce a first filtered output. In such examples, the averaging circuitry 320 produces a second filtered output responsive to averaging the second, third, fourth, and fifth oversamples. Advantageously, the averaging circuitry 320 filters the notch frequency responsive to averaging oversampled values of different sampling periods.

The multiplexer circuitry 340 of FIG. 3 determines if the filter is a multi-order filter. (Block 450). In example operation, the mode circuitry 350 of FIG. 3 controls the multiplexer circuitry 340 to set a mode of the filter circuitry 255, 260, 265. In a first mode, the multiplexer circuitry 340 provides the averaged oversample at the output of the filter circuitry 300. In a second mode, the multiplexer circuitry 340 provides the averaged oversample to the averaging circuitry 360 for further filtering. In the second mode, the additional averaging of the oversamples increases the accuracy of filtering the notch frequency. In both examples, the averaging circuitry 320, 360, 370 average the number of samples (N) of the number of samples circuitry 330. The number of times oversamples values are averaged (M), which is set by the mode, determines number of cascaded averages. In the first mode, the filter circuitry 300 averages oversamples once. In the second mode, the filter circuitry averages the oversamples three times. Such averaging forms a cascade moving average filter, which is represented by Equation (1).

$$H ( z ) = {( \frac{1 + {z}^{- 1} + ⋯ + {z}^{- ( N - 1 )}}{N} )}^{M} \qquad Equation ( 1 )$$

If the multiplexer circuitry 340 determines that the filter is a multi-order filter (e.g., Block 450 returns a result of YES), the averaging circuitry 360 of FIG. 3 averages a number of samples of the averaged data. (Block 455). In example operations, the number of samples circuitry 330 structures the averaging circuitry 360 to average a number of samples. In such example operations, the averaging circuitry 360 averages the number of samples across a plurality of the sampling periods. Advantageously, the averaging circuitry 360 filters the notch frequency responsive to averaging oversamples of different sampling periods.

The averaging circuitry 370 of FIG. 3 averages another number of samples of the averaged data. (Block 460). In example operations, the number of samples circuitry 330 structures the averaging circuitry 370 to average a number of samples. In such example operations, the averaging circuitry 370 averages the number of samples across a plurality of the sampling periods. Advantageously, the averaging circuitry 370 filters the notch frequency responsive to averaging oversamples of different sampling periods.

If the multiplexer circuitry 340 determines that the filter is not a multi-order filter (e.g., Block 450 returns a result of NO) or control proceeds from Block 460, the control buffer circuitry 150 of FIG. 1 buffers the filtered data. (Block 465). In example operations, the filter circuitry 255, 260, 265, 300 attenuate signals at the notch frequency to provide digital output values. In such example operations, the control buffer circuitry 150 buffers the digital output values of the filter circuitry 255, 260, 265 to reconstruct the digital representation of an analog signal. Advantageously, the control buffer circuitry 150 sequences the outputs of the notch filter circuitry 140 to represent the analog input of the ADC 130. Control proceeds to Block 405.

Example methods are described with reference to the flowchart illustrated in FIG. 4. However, many other methods of implementing the filter circuitry 255, 260, 265 of FIGS. 2 and 3 or more generally the notch filter circuitry 140 of FIGS. 1 and 2 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

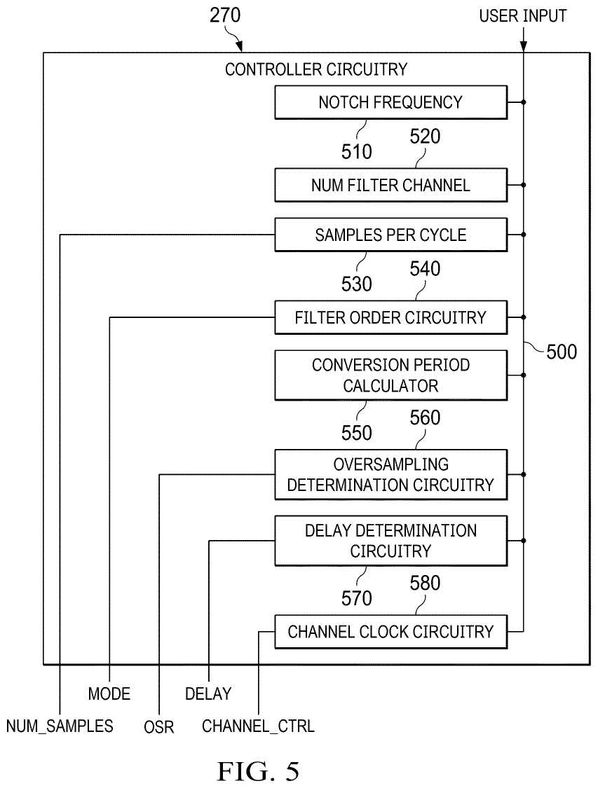

FIG. 5 is a block diagram of an example implementation of the controller circuitry 270 of FIG. 2. The controller circuitry 270 of FIG. 5 may be instantiated (e.g., creating an instance of, bring into being for any length of time, materialize, implement, etc.) by programmable circuitry such as a Central Processor Unit (CPU) executing first instructions. Also or alternatively, the controller circuitry 270 of FIG. 5 may be instantiated (e.g., creating an instance of, bring into being for any length of time, materialize, implement, etc.) by (i) an Application Specific Integrated Circuit (ASIC) or (ii) a Field Programmable Gate Array (FPGA) structured or configured in response to execution of second instructions to perform operations corresponding to the first instructions. Some or all of the circuitry of FIG. 5 may, thus, be instantiated at the same or different times. Some or all of the circuitry of FIG. 5 may be instantiated, for example, in one or more threads executing concurrently on hardware or in series on hardware. Moreover, in some examples, some or all of the circuitry of FIG. 5 may be implemented by microprocessor circuitry executing instructions or FPGA circuitry performing operations to implement one or more virtual machines or containers.

In the example of FIG. 5, the controller circuitry 270 includes a bus 500, notch frequency circuitry 510, number of filter channels circuitry 520, samples per cycle circuitry 530, filter order circuitry 540, conversion period calculator circuitry 550, oversampling determination circuitry 560, delay determination circuitry 570, and channel clock circuitry 580.

The controller circuitry 270 has an input, a first output, a second output, a third output, a fourth output, and a fifth output. The input of the controller circuitry 270 is structured to be coupled to an external device. In some examples, the external device provides user inputs to the controller circuitry 270 through an interface. In other examples, the controller circuitry 270 receives values of the user input from memory circuitry. The first output of the controller circuitry 270 (OSR) is structured to be coupled to the OSR circuitry 210 of FIG. 2. The second output of the controller circuitry 270 (CHANNEL_CTRL) is structured to be coupled to the channel control circuitry 235 of FIG. 2. The third output of the controller circuitry 270 (DELAY) is structured to be coupled to the delay circuitry 240, 245, 250 of FIG. 2. The fourth output of the controller circuitry 270 (NUM_SAMPLES) is structured to be coupled to the number of samples circuitry 330 of FIG. 3. The fifth output of the controller circuitry 270 (MODE) is structured to be coupled to the mode circuitry 350 of FIG. 3.

The bus 500 is coupled to the notch frequency circuitry 510, the number of filter channel circuitry 520, the samples per cycle circuitry 530, the filter order circuitry 540, the conversion period calculator circuitry 550, the oversampling determination circuitry 560, the delay determination circuitry 570, the channel clock circuitry 580, and the input of the controller circuitry 270.

The notch frequency circuitry 510 is coupled to the bus 500. In some examples, the notch frequency circuitry 510 is instantiated by programmable circuitry executing notch frequency instructions to perform operations such as those represented by the flowchart of FIG. 6.

The number of filter channels circuitry 520 is coupled to the bus 500. In some examples, the number of filter channels circuitry 520 is instantiated by programmable circuitry executing number of filter channels instructions to perform operations such as those represented by the flowchart of FIG. 6.

The samples per cycle circuitry 530 is coupled to the bus 500 and the fourth output of the controller circuitry 270 (NUM_SAMPLES). In some examples, the samples per cycle circuitry 530 is instantiated by programmable circuitry executing samples per cycle instructions to perform operations such as those represented by the flowchart of FIG. 6.

The filter order circuitry 540 is coupled to the bus 500 and the fifth output of the controller circuitry 270 (MODE). In some examples, the filter order circuitry 540 is instantiated by programmable circuitry executing filter order circuitry instructions to perform operations such as those represented by the flowchart of FIG. 6.

The conversion period calculator circuitry 550 is coupled to the bus 500. In some examples, the conversion period calculator circuitry 550 is instantiated by programmable circuitry executing conversion period calculator instructions to perform operations such as those represented by the flowchart of FIG. 6.

The oversampling determination circuitry 560 is coupled to the bus 500 and the first output of the controller circuitry 270 (OSR). In some examples, the oversampling determination circuitry 560 is instantiated by programmable circuitry executing oversampling determination instructions to perform operations such as those represented by the flowchart of FIG. 6.

The delay determination circuitry 570 is coupled to the bus 500 and the third output of the controller circuitry 270 (DELAY). In some examples, the delay determination circuitry 570 is instantiated by programmable circuitry executing delay determination instructions to perform operations such as those represented by the flowchart of FIG. 6.

The channel clock circuitry 580 is coupled to the bus 500 and the second output of the controller circuitry 270 (CHANNEL_CNTRL). In some examples, the channel clock circuitry 580 is instantiated by programmable circuitry executing channel clock instructions to perform operations such as those represented by the flowchart of FIG. 6.

FIG. 6 is a flowchart representative of example machine-readable instructions or example operations 600 that may be at least one of executed, instantiated, or performed using an example implementation of the controller circuitry 270 of FIGS. 2 and 5 or more generally the notch filter circuitry 140 of FIGS. 1 and 2.

The example operations 600 of FIG. 6 begin at Block 605 at which the notch frequency circuitry 510 of FIG. 5 receives a notch frequency. The notch frequency is a frequency is a target frequency within the bandwidth of the delta-sigma ADC circuitry 100 of FIG. 1. The notch filter circuitry 140 filters signals of the notch frequency from the output of the ADC 130 of FIG. 1. In some examples, the notch frequency corresponds to a frequency that noisy signals are likely to have. For example, if a grid connection provides power at sixty hertz (Hz), the notch filter circuitry 140 filters noise from the grid connection responsive to setting the notch frequency to sixty hertz. In example operations, the notch frequency circuitry 510 stores the notch frequency. In some examples, the notch frequency of the notch frequency circuitry 510 is set by a user input. In other examples, the notch frequency of the notch frequency circuitry 510 is set responsive to loading the notch frequency from memory. Advantageously, the notch filter circuitry 140 allows circuitry to filter signals having the notch frequency, which is inside the bandwidth of a system.

The number of filter channels circuitry 520 of FIG. 5 receives a number of filter channels. (Block 610). A filter channel of the notch filter circuitry 140 includes one of the delay circuitry 240, 245, 250 of FIG. 2 and one of the filter circuitry 255, 260, 265, 300 of FIGS. 2 and 3. In the example of FIG. 2, the delay circuitry 240 and the filter circuitry 255 form a first filter channel, the delay circuitry 245 and the filter circuitry 260 form a second filter channel, and the delay circuitry 250 and the filter circuitry 265 form a third filter channel. Alternatively, the notch filter circuitry 140 may be modified to include any number of filter channels. In example operations, the number of filter channels circuitry 520 stores the number of filter channels of the notch filter circuitry 140. In some examples, the number of filter channels of the number of filter channels circuitry 520 is set by a user input. In other examples, the number of filter channels of the number of filter channels circuitry 520 is set in memory.

The filter order circuitry 540 of FIG. 5 receives a filter order. (Block 615). The filter order corresponds to the number of oversamples the filter circuitry 255, 260, 265, 300 averages to filter the notch frequency. In some examples, such as in FIG. 3, the filter circuitry 300 supports two filter orders, which are set by a filter mode. In a first mode, the mode circuitry 350 of FIG. 3 structures the multiplexer circuitry 340 of FIG. 3 to provide the output of the averaging circuitry 320 at the output of the filter circuitry 300. In a second mode, the mode circuitry 350 structures the multiplexer circuitry 340 to provide the output of the averaging circuitry 370 of FIG. 3 at the output of the filter circuitry 300. In the second mode, the filter circuitry 300 is considered to have a high filter order responsive to filtering by the averaging circuitry 320, 360, 370 of FIG. 3. In example operations, the filter order circuitry 540 stores the filter order of the filter circuitry 255, 260, 265, 300. In some examples, the filter order of the filter order circuitry 540 is set by a user input. In other examples, the filter order of the filter order circuitry 540 is set in memory. Also, in some examples, the filter order is set in reference to the mode of the filter circuitry 255, 260, 265, 300.

The samples per cycle circuitry 530 of FIG. 5 receives a number of samples per cycle. (Block 620). The number of samples per cycle represents the number of samples of signals of the notch frequency the averaging circuitry 320, 360, 370 averages across any given period of the notch frequency. In some examples, the number of samples circuitry 330 of FIG. 3 structures the averaging circuitry 320, 360, 370 to average the same number of samples per cycle. Alternatively, the averaging circuitry 320, 360, 370 may average different number of samples per cycle of the notch frequency. In example operations, the samples per cycle circuitry 530 stores the number of samples per cycle of the filter circuitry 255, 260, 265, 300. In some examples, the number of samples per cycle of the samples per cycle circuitry 530 is set by a user input. In other examples, the number of samples per cycle of the samples per cycle circuitry 530 is set in memory. Also, in some examples, the number of samples per cycle is set in reference to the averaging circuitry 320, 360, 370.

The conversion period calculator circuitry 550 of FIG. 5 calculates a line cycle period (t_line_cycle) based on the notch frequency (f_notch). (Block 625). The line cycle period is the period of a single cycle of a signal at the notch frequency. In example operations, the conversion period calculator circuitry 550 determines the line cycle period responsive to dividing one by the notch frequency. In some examples, the conversion period calculator circuitry 550 may determine the line cycle period in reference to a number of cycles of a reference clock signal. The line cycle period may be determined using Equation (2).

$$t\_line \_cycle = \frac{1}{f\_notch} \qquad Equation ( 2 )$$

The conversion period calculator circuitry 550 calculates a conversion period (t_conv) based on the line cycle period (t_line_cycle), the number of channels (N_ch), and the number of samples (N_samples). (Block 630). The conversion period is a division of a period of the notch frequency by a total number of samples needed to cycle through the filter channels of the notch filter circuitry 140. For example, if the averaging circuitry 320 averages four samples, the number of samples is four, and if the notch filter circuitry 140 has eight instances of the filter circuitry 300, the number of channels is eight. In example operations, the conversion period evenly divides the line cycle period between each instance of the filter circuitry 300. In such example operations, as further illustrated by FIGS. 7 and 8, during a first conversion period the multiplexer circuitry 230 supplies values to the delay circuitry 240, during a second conversion period the multiplexer circuitry 230 supplies values to the delay circuitry 245, and during a final conversion period the multiplexer circuitry 230 supplies value to the delay circuitry 250. Advantageously, the conversion period calculator circuitry 550 evenly divides the line cycle period between the filter channels of the filter circuitry 255, 260, 265.

$$t\_conv = \frac{t\_line \_cycle}{N\_ch * N\_samples} \qquad Equation ( 3 )$$

The oversampling determination circuitry 560 of FIG. 5 determines an oversampling rate. (Block 635). As further described in connection with FIG. 4, the decimation filter circuitry 205 of FIG. 2 decimates digital input values from the ADC 130 by an oversampling rate (OSR). In such examples, the decimation filter circuitry 205 provides oversampled values to the filter circuitry 255, 260, 265. In example operations, the filter circuitry 255, 260, 265 may receive a plurality of oversampled values during the corresponding conversion period. For example, the conversion period can be long enough for the decimation filter circuitry 205 to provide four oversampled values at a first OSR or two oversampled values at a second OSR. In such examples, the second OSR is twice the first OSR. Some example OSRs include thirty-two samples, sixty-four samples, one-hundred and twenty-eight samples, etc. In some example operations, the oversampling determination circuitry 560 determines an OSR using an input sample rate and the conversion period. Also, in examples using the settling circuitry 310 of FIG. 3, the oversampling determination circuitry 560 may further consider a minimum number of oversampled values in the conversion period. For example, if the settling circuitry 310 discards the first three samples of a conversion period, the oversampling determination circuitry 560 selects an OSR that provides at least four oversamples per conversion period.

The delay determination circuitry 570 of FIG. 5 determines a filter delay (t_delay) using a filter order (ORD), the conversion period (t_conv), and the oversampling rate (N_OSR). (Block 640). The filter order represents the number of oversamples per conversion period, the filter circuitry 300 needs. In some examples, the oversampling determination circuitry 560 determines the conversion period is not divisible by the determined OSR. In such examples, the delay circuitry 240, 245, 250 implement a filter delay to align the conversion periods with the OSR. Also, in examples using the settling circuitry 310, the oversampling determination circuitry 560 may need a minimum number of oversampled values in the conversion period. For example, if the settling circuitry 310 discards the first three samples of a conversion period, the filter order is four. In such example operations, the filter delay corresponds to a portion of the conversion period that aligns the filter order number of samples to the end of the conversion period. Such a filter delay may be found using Equation (4). Also, example conversion periods are further illustrated and described in connection with FIGS. 7 and 8.

$$t\_delay = t\_conv - ( ORD * N\_OSR ) \qquad Equation ( 4 )$$

The delay determination circuitry 570 determines if the filter delay is greater than zero. (Block 645). In some examples, the delay determination circuitry 570 may determine the decimation filter circuitry 205 is unable to provide the filter order number of samples in a given conversion period. In such examples, the determined OSR of Block 635 cannot be implemented.

If the delay determination circuitry 570 determines that the filter delay is not greater than zero (e.g., Block 645 returns a result of NO), the oversampling determination circuitry 560 determines another oversampling rate. (Block 650). In example operations, the oversampling determination circuitry 560 selects a different OSR responsive to a determination that the conversion period is not long enough to support the previous OSR.

If the delay determination circuitry 570 determines that the filter delay is greater than zero (e.g., Block 645 returns a result of YES), the delay determination circuitry 570 sets the delays of the filter channels. (Block 655). In example operations, the delay determination circuitry 570 sets the delays of the delay circuitry 240, 245, 250 to the filter delay of Block 640. In such example operations, the delay circuitry 240, 245, 250 align the oversamples of a conversion period for the filter circuitry 255, 260, 265. In some examples, such delays of the delay circuitry 240, 245, 250 correspond to the filter delay of Equation (4). In other examples, a different process of delaying or altering timing of oversamples may be used. Advantageously, the filter delays of the delay circuitry 240, 245, 250 align oversamples for filtering by the filter circuitry 255, 260, 265.

The oversampling determination circuitry 560 sets the oversampling rate. (Block 660). In example operations, the oversampling determination circuitry 560 provides the oversample ratio to the OSR circuitry 210. In such examples, the OSR circuitry 210 structures the decimation filter circuitry 205 for decimation using the selected OSR.

The filter order circuitry 540 sets the mode of the filter channels. (Block 665). In example operations, the filter order circuitry 540 provides a value representing the mode of the filter circuitry 255, 260, 265 to the mode circuitry 350. In such examples, the mode circuitry 350 controls the multiplexer circuitry 340.

The samples per cycle circuitry 530 sets the number of samples. (Block 670). In example operations, the samples per cycle circuitry 530 provides the number of samples to the number of samples circuitry 330. In such examples, the number of samples circuitry 330 structures the averaging circuitry 320, 360, 370 for averaging the number of samples. Control proceeds to return.

Example methods are described with reference to the flowchart illustrated in FIG. 6. However, many other methods of implementing the controller circuitry 270 of FIGS. 2 and 5 or more generally the notch filter circuitry 140 of FIGS. 1 and 2 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

FIG. 7 is a timing diagram 700 of example operations of the notch filter circuitry 140 of FIGS. 1 and 2 to filter an example notch signal 710 at a notch frequency. The notch signal 710 represents a signal that the notch filter circuitry 140 filters responsive to the operations 400, 600 of FIGS. 4 and 6. In some examples, a period of the notch signal 710 is referred to as the line cycle period.

Prior to a first time 725, a first conversion period begins. During the first conversion period, the multiplexer circuitry 230 of FIG. 2 provides oversamples from the decimation filter circuitry 205 of FIG. 2 to a first filter channel. In the example of FIG. 2, the first filter channel includes the delay circuitry 240 of FIG. 2 and the filter circuitry 255 of FIG. 2. At the first time 725, the filter circuitry 255 accumulates a first channel oversample (0-1) of the notch signal 710.

Between the first time 725 and a second time 730 is a second conversion period. During the second conversion period, the multiplexer circuitry 230 provides oversamples from the decimation filter circuitry 205 to a second filter channel. In the example of FIG. 2, the second filter channel includes the delay circuitry 245 of FIG. 2 and the filter circuitry 260 of FIG. 2. At the second time 730, the filter circuitry accumulates a second channel oversample (1-1) of the notch signal 710.

After the second time 730, a third conversion period (not illustrated for simplicity) occurs. During the third conversion period, the multiplexer circuitry 230 provides oversamples from the decimation filter circuitry 205 to a third filter channel. In the example of FIG. 2, the third filter channel includes the delay circuitry 250 of FIG. 2 and the filter circuitry 265 of FIG. 2. Although in the example of FIGS. 2 and 7, the notch filter circuitry 140 is illustrated and described in connection with three filter channels, in some examples, the notch filter circuitry 140 may include any number of filter channels.

At a third time 735, a fourth conversion period ends with the filter circuitry 255 accumulating another first channel oversample (0-2) of the notch signal 710. At a fourth time 740, a fifth conversion period ends with the filter circuitry 260 accumulating another second channel oversample (1-2) of the notch signal 710. Similar to between the times 730, 735, between the fourth time 740 and a fifth time 745, a sixth conversion period occurs with the filter circuitry 265 accumulating another third channel oversample.

At the fifth time 745, a seventh conversion period ends with the filter circuitry 255 accumulating yet another first channel oversample (0-3) of the notch signal 710. At a sixth time 750, an eighth conversion period ends with the filter circuitry 260 accumulating yet another second channel oversample (1-3) of the notch signal 710. Similar to between the times 740, 745, between the sixth time 750 and a seventh time 755, a ninth conversion period occurs with the filter circuitry 265 accumulating yet another third channel oversample.

At the seventh time 755, a tenth conversion period ends with the filter circuitry 255 accumulating a final first channel oversample (0-4) of the notch signal 710. At an eighth time 760, an eleventh conversion period ends with the filter circuitry 260 accumulating a final second channel oversample (1-4) of the notch signal 710. Similar to between the times 750, 755, between the eighth time 760 and a ninth time 765, a twelfth conversion period occurs with the filter circuitry 265 accumulating a final third channel oversample.

At the time 755, the filter circuitry 255 averages the accumulated first channel oversamples from the times 725, 735, 745, 755. Advantageously, the amplitudes of the notch signal 710 at the times 725, 745 average to approximately zero and the amplitudes of the notch signal 710 at the times 735, 755 average to approximately zero. Advantageously, the filter circuitry 255 attenuates the notch signal 710 responsive to averaging oversamples at the times 725, 735, 745, 755.

At the time 760, the filter circuitry 260 averages the accumulated second channel oversamples from the times 730, 740, 750, 760. Advantageously, the amplitudes of the notch signal 710 at the times 730, 750 average to approximately zero and the amplitudes of the notch signal 710 at the times 740, 760 average to approximately zero. Advantageously, the filter circuitry 260 attenuates the notch signal 710 responsive to averaging oversamples at the times 730, 740, 750, 760.

At the ninth time 765, the filter circuitry 255 accumulates another first channel oversample. However, at the ninth time 765, the filter circuitry averages the accumulated first channel oversamples from the times 735, 745, 755, 765. Such averaging is referred to as a moving average or windowing. At the ninth time 765, the filter circuitry 255 provides another filtered output. Advantageously, after the latency between the times 725, 760, the notch filter circuitry 140 provides another filtered output every conversion period.

In the example of FIG. 7, a line cycle period occurs between the times 725, 765. The line cycle period is a period of the notch signal 710. During subsequent sampling operations, the sampling of the times 725, 730, 735, 740, 745, 750, 755, 760 occur periodically. Although in the example of FIG. 7, the averaging circuitry 320 averages four oversamples, in other examples, the averaging circuitry 320 may average any number of oversamples. In such alternative examples, the conversion period may be modified to reflect any number of oversamples. Also, in some examples, the filter delay is modified to prevent the filter circuitry 255, 260, 265 from averaging oversamples corresponding to zero-crossings of the notch signal 710. Advantageously, ensuring oversample averaging occurs at non-zero-crossings improves the filtering of the notch filter circuitry 140.

FIG. 8 is a timing diagram 800 of example operations of the plurality of example filter circuitry 255, 260, 265, 300 of FIGS. 2 and 3 to filter the example notch signal 710 of FIG. 7 at the notch frequency. In the example of FIG. 8, the timing diagram 800 illustrates a first conversion period 805, a second conversion period 810, a third conversion period 815, a line cycle period 820, and a fourth conversion period 825. The conversion periods 805, 810, 815, 825 represent the conversion periods from Block 630 of FIG. 6, which corresponds to Equation (3). The line cycle period 820 represents a period of the notch signal 710. The line cycle period 820 may be found using Equation (2).

The example conversion periods 805, 810, 815, 825 include an example filter delay 830, a first example oversample 835, a second example oversample 840, a third example oversample 845, and a fourth example oversample 850. In example operations, filter delay 830 represents the filter delay from Block 640 of FIG. 6, which corresponds to Equation (4). The filter delay 830 aligns the oversamples 835, 840, 845, 850 for the conversion periods 805, 810, 815, 825. In the example of FIG. 8, the filter circuitry 255, 260, 265 of FIG. 2 include the example settling circuitry 310 of FIG. 3. In such examples, the settling circuitry 310 allows the oversamples to settle by removing the oversamples 835, 840, 845. In such example operations, the averaging circuitry 320 of FIG. 3 averages the oversamples 850, which are the fourth oversamples of the conversion period 805. Alternatively, in some examples without the settling circuitry 310, the filter delay 830 or the OSR of the decimation filter circuitry 205 may be modified to provide the oversample 850. Advantageously, the settling circuitry 310 allows oversampled values to settle prior to filtering the notch signal 710.

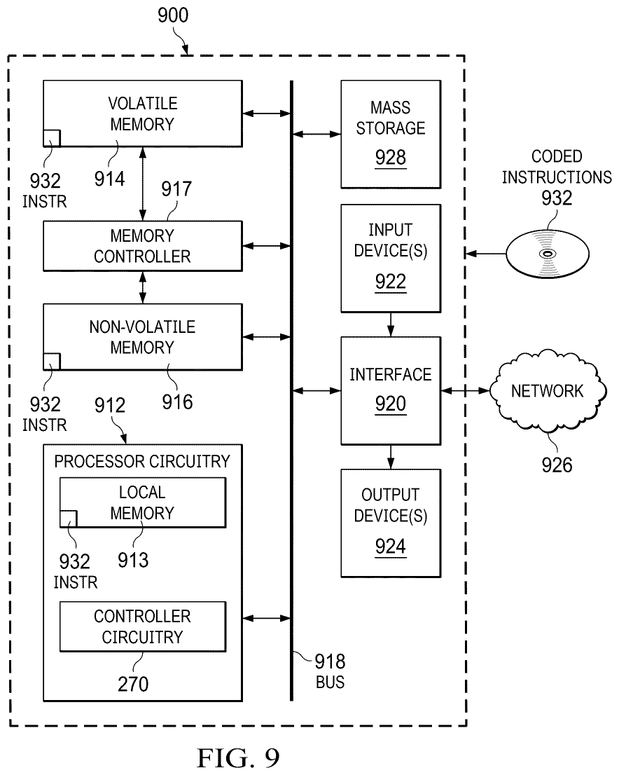

FIG. 9 is a block diagram of an example programmable circuitry platform 900 structured to one or a combination of execute or instantiate one or more of the example machine-readable instructions or the example operations of FIGS. 4 and 6 to implement the controller circuitry 270 of FIGS. 2 and 5 or more generally, the notch filter circuitry 140 of FIGS. 1 and 2. The programmable circuitry platform 900 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing or electronic device.

The programmable circuitry platform 900 of the illustrated example includes programmable circuitry 912. The programmable circuitry 912 of the illustrated example is hardware. For example, the programmable circuitry 912 can be implemented by one or more integrated circuits, logic circuits, FPGAs, microprocessors, CPUs, GPUs, DSPs, or microcontrollers from any desired family or manufacturer. The programmable circuitry 912 may be implemented by one or more semiconductor based (e.g., silicon based) devices. In this example, the programmable circuitry 912 implements the controller circuitry 270 of FIGS. 2 and 5.

The programmable circuitry 912 of the illustrated example includes a local memory 913 (e.g., a cache, registers, etc.). The programmable circuitry 912 of the illustrated example is in communication with main memory 914, 916, which includes a volatile memory 914 and a non-volatile memory 916, by a bus 918. The volatile memory 914 may be implemented by one or more Synchronous Dynamic Random Access Memory (SDRAM), Dynamic Random Access Memory (DRAM), RAMBUS® Dynamic Random Access Memory (RDRAM®), or any other type of RAM device. The non-volatile memory 916 may be implemented by one or a combination of flash memory or any other desired type of memory device. Access to the main memory 914, 916 of the illustrated example is controlled by a memory controller 917. In some examples, the memory controller 917 may be implemented by one or more integrated circuits, logic circuits, microcontrollers from any desired family or manufacturer, or any other type of circuitry to manage the flow of data going to and from the main memory 914, 916.

The programmable circuitry platform 900 of the illustrated example also includes interface circuitry 920. The interface circuitry 920 may be implemented by hardware in according to any type of interface standard, such as an Ethernet interface, a universal serial bus (USB) interface, a Bluetooth® interface, a near field communication (NFC) interface, a Peripheral Component Interconnect (PCI) interface, or a Peripheral Component Interconnect Express (PCIe) interface.

In the illustrated example, one or more input devices 922 are connected to the interface circuitry 920. The input device(s) 922 permit(s) a user (e.g., a human user, a machine user, etc.) to enter one of or a combination of data or commands into the programmable circuitry 912. The input device(s) 922 can be implemented by, for example, one of or a combination of an audio sensor, a microphone, a camera (still or video), a keyboard, a button, a mouse, a touchscreen, a trackpad, a trackball, an isopoint device, or a voice recognition system.

One or more output devices 924 are also connected to the interface circuitry 920 of the illustrated example. The output device(s) 924 can be implemented, for example, by one of or a combination of display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, or speaker. The interface circuitry 920 of the illustrated example, thus, includes one of or a combination of a graphics driver card, a graphics driver chip, or graphics processor circuitry such as a GPU.

The interface circuitry 920 of the illustrated example also includes a communication device such as one of or a combination of a transmitter, a receiver, a transceiver, a modem, a residential gateway, a wireless access point, or a network interface to facilitate exchange of data with external machines (e.g., computing devices of any kind) by a network 926. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 900 of the illustrated example also includes one or more mass storage discs or devices 928 to store one or more of firmware, software, or data. Examples of such mass storage discs or devices 928 include one or more magnetic storage devices (e.g., floppy disk, drives, HDDs, etc.), optical storage devices (e.g., Blu-ray disks, CDs, DVDs, etc.), RAID systems, or solid-state storage discs or devices such as flash memory devices and SSDs.

The machine-readable instructions 932, which may be implemented by the machine-readable instructions of FIGS. 4 and 6, may be stored in one of or a combination of the mass storage device 928, in the volatile memory 914, in the non-volatile memory 916, or on at least one non-transitory computer readable storage medium such as a CD or DVD which may be removable.

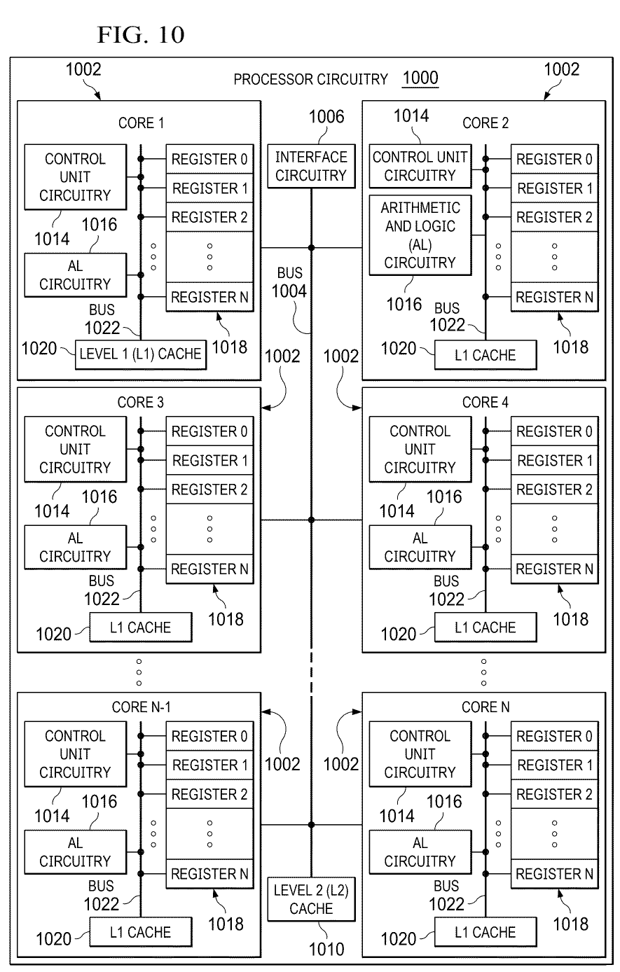

FIG. 10 is a block diagram of an example implementation of the programmable circuitry 912 of FIG. 9. In this example, the programmable circuitry 912 of FIG. 9 is implemented by a microprocessor 1000. For example, the microprocessor 1000 may be a general-purpose microprocessor (e.g., general-purpose microprocessor circuitry). The microprocessor 1000 executes some or all of the machine-readable instructions of the flowcharts of FIGS. 4 and 6 to effectively instantiate the circuitry of FIG. 5 as logic circuits to perform operations corresponding to those machine-readable instructions. In some such examples, the circuitry of FIGS. 2 and 5 are instantiated by the hardware circuits of the microprocessor 1000 in combination with the machine-readable instructions. For example, the microprocessor 1000 may be implemented by multi-core hardware circuitry such as a CPU, a DSP, a GPU, an XPU, etc. Although it may include any number of example cores 1002 (e.g., 1 core), the microprocessor 1000 of this example is a multi-core semiconductor device including N cores. The cores 1002 of the microprocessor 1000 may operate independently or may cooperate to execute machine-readable instructions. For example, machine code corresponding to a firmware program, an embedded software program, or a software program may be executed by one of the cores 1002 or may be executed by multiple ones of the cores 1002 at the same or different times. In some examples, the machine code corresponding to the firmware program, the embedded software program, or the software program is split into threads and executed in parallel by two or more of the cores 1002. The software program may correspond to a portion or all of the machine-readable instructions or operations represented by the flowcharts of FIGS. 4 and 6.

The cores 1002 may communicate by a first example bus 1004. In some examples, the first bus 1004 may be implemented by a communication bus to effectuate communication associated with one(s) of the cores 1002. For example, the first bus 1004 may be implemented by at least one of an Inter-Integrated Circuit (I2C) bus, a Serial Peripheral Interface (SPI) bus, a PCI bus, or a PCIe bus. Also or alternatively, the first bus 1004 may be implemented by any other type of computing or electrical bus. The cores 1002 may receive data, instructions, and signals from one or more external devices by example interface circuitry 1006. The cores 1002 may output data, instructions, and signals to the one or more external devices by the interface circuitry 1006. Although the cores 1002 of this example include example local memory 1020 (e.g., Level 1 (L1) cache that may be split into an L1 data cache and an L1 instruction cache), the microprocessor 1000 also includes example shared memory 1010 that may be shared by the cores (e.g., Level 2 (L2 cache)) for high-speed access to data and instructions. Data and instructions may be transferred (e.g., shared) by one of or a combination of writing to or reading from the shared memory 1010. The local memory 1020 of each of the cores 1002 and the shared memory 1010 may be part of a hierarchy of storage devices including multiple levels of cache memory and the main memory (e.g., the main memory 914, 916 of FIG. 9). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 1002 may be referred to as a CPU, DSP, GPU, etc., or any other type of hardware circuitry. Each core 1002 includes control unit circuitry 1014, arithmetic and logic (AL) circuitry (sometimes referred to as an ALU) 1016, a plurality of registers 1018, the local memory 1020, and a second example bus 1022. Other structures may be present. For example, each core 1002 may include vector unit circuitry, single instruction multiple data (SIMD) unit circuitry, load/store unit (LSU) circuitry, branch/jump unit circuitry, floating-point unit (FPU) circuitry, etc. The control unit circuitry 1014 includes semiconductor-based circuits structured to control (e.g., coordinate) data movement within the corresponding core 1002. The AL circuitry 1016 includes semiconductor-based circuits structured to perform one or more mathematic or logic operations on the data within the corresponding core 1002. The AL circuitry 1016 of some examples performs integer-based operations. In other examples, the AL circuitry 1016 also performs floating-point operations. In yet other examples, the AL circuitry 1016 may include first AL circuitry that performs integer-based operations and second AL circuitry that performs floating-point operations. In some examples, the AL circuitry 1016 may be referred to as an Arithmetic Logic Unit (ALU).

The registers 1018 are semiconductor-based structures to store data and instructions such as results of one or more of the operations performed by the AL circuitry 1016 of the corresponding core 1002. For example, the registers 1018 may include vector register(s), SIMD register(s), general-purpose register(s), flag register(s), segment register(s), machine-specific register(s), instruction pointer register(s), control register(s), debug register(s), memory management register(s), machine check register(s), etc. The registers 1018 may be arranged in a bank as shown in FIG. 10. Alternatively, the registers 1018 may be organized in any other arrangement, format, or structure, such as by being distributed throughout the core 1002 to shorten access time. The second bus 1022 may be implemented by at least one of an I2C bus, a SPI bus, a PCI bus, or a PCIe bus.

Each core 1002 or, more generally, the microprocessor 1000 may include additional or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) or other circuitry may be present. The microprocessor 1000 is a semiconductor device fabricated to include many transistors interconnected to implement the structures described above in one or more integrated circuits (ICs) contained in one or more packages.

The microprocessor 1000 may include or cooperate with one or more accelerators (e.g., acceleration circuitry, hardware accelerators, etc.). In some examples, accelerators are implemented by logic circuitry to perform certain tasks more quickly and efficiently than can be done by a general-purpose processor. Examples of accelerators include ASICs and FPGAs such as those described herein. A GPU, DSP, or other programmable device can also be an accelerator. Accelerators may be on-board the microprocessor 1000, in the same chip package as the microprocessor 1000, or in one or more separate packages from the microprocessor 1000.

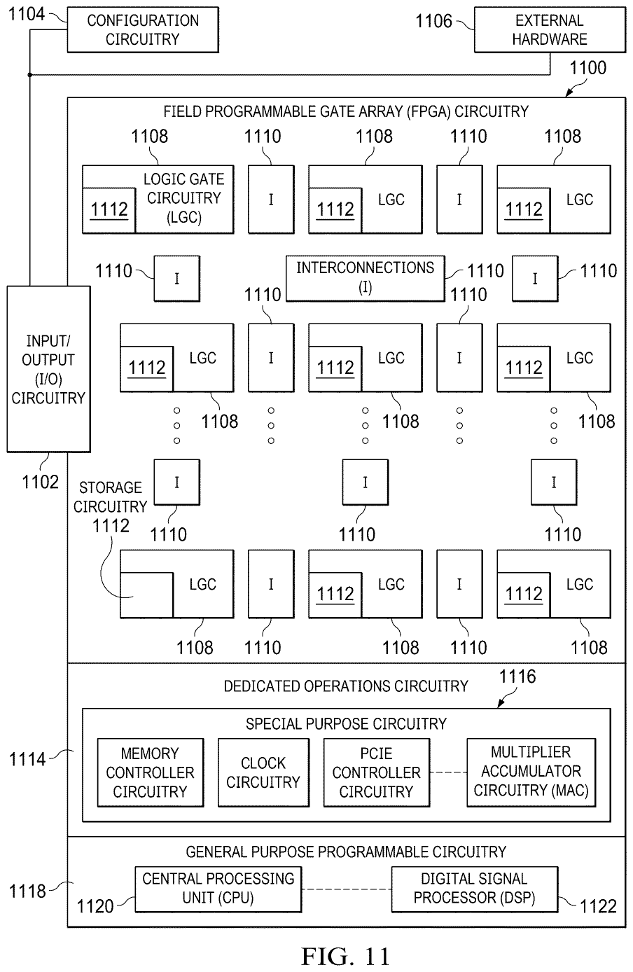

FIG. 11 is a block diagram of another example implementation of the programmable circuitry 912 of FIG. 9. In this example, the programmable circuitry 912 is implemented by FPGA circuitry 1100. For example, the FPGA circuitry 1100 may be implemented by an FPGA. The FPGA circuitry 1100 can be used, for example, to perform operations that could otherwise be performed by the example microprocessor 1000 of FIG. 10 executing corresponding machine-readable instructions. However, once configured, the FPGA circuitry 1100 instantiates the operations and functions corresponding to the machine-readable instructions in hardware and, thus, can often execute the operations/functions faster than they could be performed by a general-purpose microprocessor executing the corresponding software.

More specifically, in contrast to the microprocessor 1000 of FIG. 10 described above (which is a general purpose device that may be programmed to execute some or all of the machine-readable instructions represented by the flowchart(s) of FIGS. 4 and 6 but whose interconnections and logic circuitry are fixed once fabricated), the FPGA circuitry 1100 of the example of FIG. 11 includes interconnections and logic circuitry that may be one of or a combination of configured, structured, programmed, and interconnected in different ways after fabrication to instantiate, for example, some or all of the operations/functions corresponding to the machine-readable instructions represented by the flowchart(s) of FIGS. 4 and 6. In particular, the FPGA circuitry 1100 may be thought of as an array of logic gates, interconnections, and switches. The switches can be programmed to change how the logic gates are interconnected by the interconnections, effectively forming one or more dedicated logic circuits (unless and until the FPGA circuitry 1100 is reprogrammed). The configured logic circuits enable the logic gates to cooperate in different ways to perform different operations on data received by input circuitry. Those operations may correspond to some or all of the instructions (e.g., the software and/or firmware) represented by the flowchart(s) of FIGS. 4 and 6. As such, the FPGA circuitry 1100 may be at least one of configured or structured to effectively instantiate some or all of the operations/functions corresponding to the machine-readable instructions of the flowchart(s) of FIGS. 4 and 6 as dedicated logic circuits to perform the operations/functions corresponding to those software instructions in a dedicated manner analogous to an ASIC. Therefore, the FPGA circuitry 1100 may perform the operations/functions corresponding to the some or all of the machine-readable instructions of FIGS. 4 and 6 faster than the general-purpose microprocessor can execute the same.

In the example of FIG. 11, the FPGA circuitry 1100 is at least one of configured or structured in response to being programmed (and/or reprogrammed one or more times) based on a binary file. In some examples, the binary file may be one of or both of compiled or generated based on instructions in a hardware description language (HDL) such as Lucid, Very High-Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 1100 of FIG. 11 may at least one of access or load the binary file to cause the FPGA circuitry 1100 of FIG. 11 to be at least one of configured or structured to perform the one or more operations/functions. For example, the binary file may be implemented by one of or a combination of a bit stream (e.g., one or more computer-readable bits, one or more machine-readable bits, etc.), data (e.g., computer-readable data, machine-readable data, etc.), or machine-readable instructions accessible to the FPGA circuitry 1100 of FIG. 11 to at least one of configure or structure the FPGA circuitry 1100 of FIG. 11, or portion(s) thereof.

In some examples, the binary file is at least one of compiled, generated, transformed, or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is at least one of compiled, generated, or otherwise output from the uniform software platform based on the second instructions. In some examples, the FPGA circuitry 1100 of FIG. 11 may at least one of access or load the binary file to cause the FPGA circuitry 1100 of FIG. 11 to be at least one of configured or structured to perform the one or more operations/functions. For example, the binary file may be implemented by one of or a combination of a bit stream (e.g., one or more computer-readable bits, one or more machine-readable bits, etc.), data (e.g., computer-readable data, machine-readable data, etc.), or machine-readable instructions accessible to the FPGA circuitry 1100 of FIG. 11 to at least one of configure or structure the FPGA circuitry 1100 of FIG. 11, or portion(s) thereof.

The FPGA circuitry 1100 of FIG. 11, includes example input/output (I/O) circuitry 1102 to at least one of receive or output data to/from at least one of example configuration circuitry 1104 or external hardware 1106. For example, the configuration circuitry 1104 may be implemented by interface circuitry that may receive a binary file, which may be implemented by one or more of a bit stream, data, or machine-readable instructions, to configure the FPGA circuitry 1100, or portion(s) thereof. In some such examples, the configuration circuitry 1104 may receive the binary file from one of or a combination of a user, a machine (e.g., hardware circuitry (e.g., programmable or dedicated circuitry) that may implement an Artificial Intelligence/Machine Learning (AI/ML) model to generate the binary file, etc.), or any combination(s) thereof). In some examples, the external hardware 1106 may be implemented by external hardware circuitry. For example, the external hardware 1106 may be implemented by the microprocessor 1000 of FIG. 10.

The FPGA circuitry 1100 also includes an array of example logic gate circuitry 1108, a plurality of example configurable interconnections 1110, and example storage circuitry 1112. The logic gate circuitry 1108 and the configurable interconnections 1110 are configurable to instantiate one or more operations/functions that may correspond to at least some of the machine-readable instructions of FIGS. 4 and 6 and/or other desired operations. The logic gate circuitry 1108 shown in FIG. 11 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 1108 to enable configuration of one of or a combination of the electrical structures or the logic gates to form circuits to perform desired operations/functions. The logic gate circuitry 1108 may include other electrical structures such as look-up tables (LUTs), registers (e.g., flip-flops or latches), multiplexers, etc.

The configurable interconnections 1110 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 1108 to program desired logic circuits.

The storage circuitry 1112 of the illustrated example is structured to store result(s) of the one or more of the operations performed by corresponding logic gates. The storage circuitry 1112 may be implemented by registers or the like. In the illustrated example, the storage circuitry 1112 is distributed amongst the logic gate circuitry 1108 to facilitate access and increase execution speed.

The example FPGA circuitry 1100 of FIG. 11 also includes example dedicated operations circuitry 1114. In this example, the dedicated operations circuitry 1114 includes special purpose circuitry 1116 that may be invoked to implement commonly used functions to avoid the need to program those functions in the field. Examples of such special purpose circuitry 1116 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 1100 may also include example general purpose programmable circuitry 1118 such as an example CPU 1120 or an example DSP 1122. Other general purpose programmable circuitry 1118 may also or alternatively be present such as a GPU, an XPU, etc., that can be programmed to perform other operations.

Although FIGS. 10 and 11 illustrate two example implementations of the programmable circuitry 912 of FIG. 9, many other approaches are contemplated. For example, FPGA circuitry may include an on-board CPU, such as one or more of the example CPU 1120 of FIG. 10. Therefore, the programmable circuitry 912 of FIG. 9 may also be implemented by combining at least the example microprocessor 1000 of FIG. 10 and the example FPGA circuitry 1100 of FIG. 11. In some such hybrid examples, one or more cores 1002 of FIG. 10 may execute a first portion of the machine-readable instructions represented by the flowchart(s) of FIGS. 4 and 6 to perform first operation(s)/function(s), the FPGA circuitry 1100 of FIG. 11 may be at least one of configured or structured to perform second operation(s)/function(s) corresponding to a second portion of the machine-readable instructions represented by the flowcharts of FIGS. 4 and 6, and/or an ASIC may be at least one of configured or structured to perform third operation(s)/function(s) corresponding to a third portion of the machine-readable instructions represented by the flowcharts of FIGS. 4 and 6.

Some or all of the circuitry of FIG. 5 may, thus, be instantiated at the same or different times. For example, same and/or different portion(s) of the microprocessor 1000 of FIG. 10 may be programmed to execute portion(s) of machine-readable instructions at the same and/or different times. In some examples, same and/or different portion(s) of the FPGA circuitry 1100 of FIG. 11 may be at least one of configured or structured to perform operations/functions corresponding to portion(s) of machine-readable instructions at the same and/or different times.

In some examples, some or all of the circuitry of FIG. 5 may be instantiated, for example, in one or more threads executing concurrently and/or in series. For example, the microprocessor 1000 of FIG. 10 may execute machine-readable instructions in one or more threads executing concurrently and/or in series. In some examples, the FPGA circuitry 1100 of FIG. 11 may be at least one of configured or structured to carry out operations/functions concurrently and/or in series. Moreover, in some examples, some or all of the circuitry of FIG. 5 may be implemented within one or more virtual machines or containers executing on the microprocessor 1000 of FIG. 10.

In some examples, the programmable circuitry 912 of FIG. 9 may be in one or more packages. For example, at least one of the microprocessor 1000 of FIG. 10 or the FPGA circuitry 1100 of FIG. 11 may be in one or more packages. In some examples, an XPU may be implemented by the programmable circuitry 912 of FIG. 9, which may be in one or more packages. For example, the XPU may include a CPU (e.g., the microprocessor 1000 of FIG. 10, the CPU 1120 of FIG. 11, etc.) in one package, a DSP (e.g., the DSP 1122 of FIG. 11) in another package, a GPU in yet another package, and an FPGA (e.g., the FPGA circuitry 1100 of FIG. 11) in still yet another package.

While an example manner of implementing the controller circuitry 270 of FIG. 2 is illustrated in FIG. 5, one or more of the elements, processes, or devices illustrated in FIG. 5 may be combined, divided, re-arranged, omitted, eliminated, or implemented in any other way. Further, the example controller circuitry 270 of FIGS. 2 and 5 or more generally, the notch filter circuitry 140 of FIGS. 1 and 2, may be implemented by hardware alone or by hardware in combination with software and firmware. Thus, for example, any of the components of the controller circuitry 270 of FIGS. 2 and 5 or more generally, the notch filter circuitry 140 of FIGS. 1 and 2 could be implemented by programmable circuitry in combination with one or more machine-readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), or field programmable logic device(s) (FPLD(s)) such as FPGAs. Further still, the example controller circuitry 270 of FIGS. 2 and 5 or more generally, the notch filter circuitry 140 of FIGS. 1 and 2 may include one or more elements, processes, or devices in addition to, or instead of, those illustrated in FIGS. 2 and 5, or may include more than one of any or all of the illustrated elements, processes and devices.

Flowchart(s) representative of example machine-readable instructions, which may be executed by programmable circuitry to at least one of implement or instantiate the controller circuitry 270 of FIGS. 2 and 5 or more generally, the notch filter circuitry 140 of FIGS. 1 and 2 or representative of example operations which may be performed by programmable circuitry to at least one of implement or instantiate the controller circuitry 270 of FIGS. 2 and 5 or more generally, the notch filter circuitry 140 of FIGS. 1 and 2, are shown in FIGS. 4 and 6. The machine-readable instructions may be one or more executable programs or portion(s) of one or more executable programs for execution by programmable circuitry such as the programmable circuitry 912 shown in the example processor platform 900 described below in connection with FIG. 9 and may be one or more function(s) or portion(s) of functions to be performed by the example programmable circuitry (e.g., an FPGA) described below in connection with FIG. 10 or 11. In some examples, the machine-readable instructions cause an operation, a task, etc., to be carried out or performed in an automated manner in the real-world. As used herein, “automated” means without human involvement.

The program may be embodied in instructions (e.g., software and/or firmware) stored on one or more non-transitory computer readable and/or machine-readable storage medium such as one of or a combination of cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), or any other storage device or storage disk. The instructions of the non-transitory computer readable and/or machine-readable medium may program or be executed by programmable circuitry located in one or more hardware devices, but the entire program or parts thereof could alternatively be executed or instantiated by one or more hardware devices other than the programmable circuitry or embodied in dedicated hardware. The machine-readable instructions may be distributed across multiple hardware devices or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart(s) illustrated in FIGS. 4 and 6, many other methods of implementing the example controller circuitry 270 of FIGS. 2 and 5 or more generally, the notch filter circuitry 140 of FIGS. 1 and 2 may alternatively be used. For example, the order of execution of the blocks of the flowchart(s) may be changed, or some of the blocks described may be changed, eliminated, or combined. Also or alternatively, any or all of the blocks of the flow chart may be implemented by one or more hardware circuits (e.g., processor circuitry, discrete, integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations or local to one or more hardware devices (e.g., a single-core processor (e.g., a single core CPU), a multi-core processor (e.g., a multi-core CPU, an XPU, etc.)). For example, the programmable circuitry may be one of or a combination of a CPU or an FPGA located in the same package (e.g., the same integrated circuit (IC) package or in two or more separate housings), one or more processors in a single machine, multiple processors distributed across multiple servers of a server rack, multiple processors distributed across one or more server racks, etc., or any combination(s) thereof.

The machine-readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, or produce machine executable instructions. For example, the machine-readable instructions may be fragmented and stored on one or more storage devices, disks or computing devices (e.g., servers) located at the same or different locations of a network or collection of networks (e.g., in the cloud, in edge devices, etc.). The machine-readable instructions may require one or more of installation, modification, adaptation, updating, combining, supplementing, configuring, decryption, decompression, unpacking, distribution, reassignment, compilation, etc., in order to make them directly readable, interpretable, or executable by a computing device or other machine. For example, the machine-readable instructions may be stored in multiple parts, which are individually compressed, encrypted, or stored on separate computing devices, wherein the parts when decrypted, decompressed, or combined form a set of one or more computer-executable or machine executable instructions that implement one or more functions or operations that may together form a program such as that described herein.

In another example, the machine-readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine-readable instructions may need to be configured (e.g., settings stored, data input, network addresses recorded, etc.) before the machine-readable instructions or the corresponding program(s) can be executed in whole or in part. Thus, machine-readable, computer readable or machine-readable media, as used herein, may include one or a combination of instructions and program(s) regardless of the particular format or state of the machine-readable instructions or program(s).

The machine-readable instructions described herein can be represented by any past, present, or future instruction language, scripting language, programming language, etc. For example, the machine-readable instructions may be represented using any of the following languages: C, C++, Java, C-Sharp, Perl, Python, JavaScript, HyperText Markup Language (HTML), Structured Query Language (SQL), Swift, etc.

As mentioned above, the example operations of FIGS. 4 and 6 may be implemented using executable instructions (e.g., computer readable and/or machine-readable instructions) stored on one or more non-transitory computer readable or machine-readable media. As used herein, the terms non-transitory computer readable medium, non-transitory computer readable storage medium, non-transitory machine-readable medium, and non-transitory machine-readable storage medium are expressly defined to include any type of computer readable storage device or storage disk and to exclude propagating signals and to exclude transmission media. Examples of such non-transitory computer readable medium, non-transitory computer readable storage medium, non-transitory machine-readable medium, or non-transitory machine-readable storage medium include one or more optical storage devices, magnetic storage devices, an HDD, a flash memory, a read-only memory (ROM), a CD, a DVD, a cache, a RAM of any type, a register, or any other storage device or storage disk in which information is stored for any duration (e.g., for extended time periods, permanently, for brief instances, for temporarily buffering, for caching of the information). As used herein, the terms “non-transitory computer readable storage device” and “non-transitory machine-readable storage device” are defined to include any physical (mechanical, magnetic, electromechanical, or electrical) hardware to retain information for a time period, but to exclude propagating signals and to exclude transmission media. Examples of non-transitory computer readable storage devices or non-transitory machine-readable storage devices include one or a combination of random-access memory of any type, read only memory of any type, solid state memory, flash memory, optical discs, magnetic disks, disk drives, or redundant array of independent disks (RAID) systems. As used herein, the term “device” refers to physical structure such as one of or a combination of mechanical, electromechanical, or electrical equipment, hardware, or circuitry that may or may not be configured by computer readable instructions, machine-readable instructions, etc., or manufactured to execute computer-readable instructions, machine-readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and things, the phrase “at least one of A and B” refers to implementations including any of (1) at least one A, (2) at least one B, or (3) at least one A and at least one B. Similarly, as used herein in the context of describing structures, components, items, objects and things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Also, although individual features may be included in different examples or claims, these may possibly be combined, and the inclusion in different examples or claims does not imply that a combination of features is at least one of not feasible or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by at least one of the connection reference or relative movement between those elements unless otherwise indicated. As such, connection references do not necessarily infer that two elements are directly connected or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, or ordering in any way, but are merely used as at least one of labels or arbitrary names to distinguish elements for ease of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to at least one of manufacturing tolerances or other real-world imperfections. For example, “approximately” and “about” may indicate such dimensions may be within a tolerance range of +/−10% unless otherwise specified herein.

As used herein, the phrase “in communication,” including variations thereof, encompasses one of or a combination of direct communication or indirect communication through one or more intermediary components, and does not require direct physical (e.g., wired) communication or constant communication, but rather also includes selective communication at least one of periodic intervals, scheduled intervals, aperiodic intervals, or one-time events.

As used herein, “programmable circuitry” is defined to include at least one of (i) one or more special purpose electrical circuits (e.g., an application specific circuit (ASIC)) structured to perform specific operation(s) and including one or more semiconductor-based logic devices (e.g., electrical hardware implemented by one or more transistors), or (ii) one or more general purpose semiconductor-based electrical circuits programmable with instructions to perform one or more specific functions(s) or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., at least one of programmed or hardwired) at a time of manufacturing by a manufacturer to at least one of perform the function or be configurable (or re-configurable) by a user after manufacturing to perform the function/or other additional or alternative functions. The configuring may be through at least one of firmware or software programming of the device, through at least one of a construction or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as voltage and/or current sources) may instead include only the semiconductor elements within a single physical device (e.g., at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include at least one of a chassis ground, an Earth ground, a floating ground, a virtual ground, a digital ground, a common ground, or any other form of ground connection applicable to, or suitable for, the teachings of this description. Unless otherwise stated, “about,” “approximately,” or “substantially” preceding a value means+/−10 percent of the stated value, or, if the value is zero, a reasonable range of values around zero.

Modifications are possible in the described embodiments, and other embodiments are possible, within the scope of the claims.

What is claimed is:

1. An apparatus comprising:
decimation filter circuitry having an output;
multiplexer circuitry having an input, a first output and a second output, the input of the multiplexer circuitry coupled to the output of the decimation filter circuitry;
first delay circuitry having an input and an output, the input of the first delay circuitry coupled to the first output of the multiplexer circuitry;
first filter circuitry having an input coupled to the output of the first delay circuitry;
second delay circuitry having an input and an output, the input of the second delay circuitry coupled to the second output of the multiplexer circuitry; and
second filter circuitry having an input coupled to the output of the second delay circuitry.

2. The apparatus of claim 1, wherein the first filter circuitry includes averaging circuitry having an input coupled to the output of the first delay circuitry.

3. The apparatus of claim 2, wherein the multiplexer circuitry is first multiplexer circuitry, the averaging circuitry is first averaging circuitry, the first averaging circuitry further has an output, and the first filter circuitry further includes:
second multiplexer circuitry having an input, a first output, and a second output, the input of the second multiplexer circuitry coupled to the output of the first averaging circuitry; and
second averaging circuitry having an input coupled to the first output of the second multiplexer circuitry.

4. The apparatus of claim 3, wherein the second averaging circuitry further has an output, and the first filter circuitry further includes third averaging circuitry having an input and an output, the input of the third averaging circuitry coupled to the output of the second averaging circuitry, the output of the third averaging circuitry coupled to the second output of the second multiplexer circuitry.

5. The apparatus of claim 3, wherein the second multiplexer circuitry further has a control input, the first averaging circuitry further has a control input, and the first filter circuitry further includes:
number of samples circuitry having an output coupled to the control input of the first averaging circuitry; and
mode circuitry having an output coupled to the control input of the second multiplexer circuitry.

6. The apparatus of claim 1, further comprising:
offset calibration circuitry having an input and an output, the input of the offset calibration circuitry coupled to the output of the decimation filter circuitry;
gain calibration circuitry having an input and an output, the input of the gain calibration circuitry coupled to the output of the offset calibration circuitry; and
clipping circuitry having an input and an output, the input of the clipping circuitry coupled to the output of the gain calibration circuitry, the output of the clipping circuitry coupled to the input of the multiplexer circuitry.

7. The apparatus of claim 1, wherein the decimation filter circuitry further has an input, the multiplexer circuitry further has a control input, and the apparatus further comprising:
oversampling ratio (OSR) circuitry having an output coupled to the input of the decimation filter circuitry; and
channel control circuitry having an output coupled to the control input of the multiplexer circuitry.

8. The apparatus of claim 1, wherein the decimation filter circuitry further has an input, and the apparatus further comprising an analog to digital converter (ADC) having an output coupled to the input of the decimation filter circuitry.

9. The apparatus of claim 8, wherein the multiplexer circuitry is first multiplexer circuitry, the first filter circuitry further has an output, the second filter circuitry has an output, the ADC further has an input, and the apparatus further comprising:
second multiplexer circuitry having a control input and an output, the output of the second multiplexer circuitry coupled to the input of the ADC; and
buffer circuitry having a first input, a second input, and an output, the first input of the buffer circuitry coupled to the output of the first filter circuitry, the second input of the buffer circuitry coupled to the output of the second filter circuitry, the output of the buffer circuitry coupled to the control input of the second multiplexer circuitry.

10. An apparatus comprising:
an analog to digital converter (ADC) having an output;
decimation filter circuitry having an input and an output, the input of the decimation filter circuitry coupled to the output of the ADC;
multiplexer circuitry having an input, a first output, and a second output, the input of the multiplexer circuitry coupled to the output of the decimation filter circuitry;
first filter circuitry having an input coupled to the first output of the multiplexer circuitry; and
second filter circuitry having an input coupled to the second output of the multiplexer circuitry.

11. The apparatus of claim 10, further comprising:
first delay circuitry having an input and an output, the input of the first delay circuitry coupled to the first output of the multiplexer circuitry, the output of the first delay circuitry coupled to the input of the first filter circuitry; and
second delay circuitry having an input and an output, the input of the second delay circuitry coupled to the second output of the multiplexer circuitry, the output of the second delay circuitry coupled to the input of the second filter circuitry.

12. The apparatus of claim 10, wherein the first filter circuitry includes:
settling circuitry having an input and an output, the input of the settling circuitry coupled to the first output of the multiplexer circuitry; and
averaging circuitry having an input coupled to the output of the settling circuitry.

13. The apparatus of claim 12, wherein the multiplexer circuitry is first multiplexer circuitry, the averaging circuitry is first averaging circuitry, the first averaging circuitry further has an output, and the first filter circuitry further includes:
second multiplexer circuitry having an input, a first output, and a second output, the input of the second multiplexer circuitry coupled to the output of the first averaging circuitry;
second averaging circuitry having an input and an output, the input of the second averaging circuitry coupled to the first output of the second multiplexer circuitry; and
third averaging circuitry having an input and an output, the input of the third averaging circuitry coupled to the output of the second averaging circuitry, the output of the third averaging circuitry coupled to the second output of the second multiplexer circuitry.

14. The apparatus of claim 10, further comprising:
offset calibration circuitry having an input and an output, the input of the offset calibration circuitry coupled to the output of the decimation filter circuitry;
gain calibration circuitry having an input and an output, the input of the gain calibration circuitry coupled to the output of the offset calibration circuitry; and
clipping circuitry having an input and an output, the input of the clipping circuitry coupled to the output of the gain calibration circuitry, the output of the clipping circuitry coupled to the input of the multiplexer circuitry.

15. The apparatus of claim 10, wherein the decimation filter circuitry further has a control input, the multiplexer circuitry further has a control input, and the apparatus further comprising:
oversampling ratio (OSR) circuitry having an output coupled to the control input of the decimation filter circuitry; and
channel control circuitry having an output coupled to the control input of the multiplexer circuitry.

16. The apparatus of claim 10, wherein the ADC further has an input, the multiplexer circuitry is first multiplexer circuitry, the first filter circuitry further has an output, the second filter circuitry further has an output, and the apparatus further comprising:
second multiplexer circuitry having a control input and an output, the output of the second multiplexer circuitry coupled to the input of the ADC; and
buffer circuitry having a first input, a second input, and an output, the first input of the buffer circuitry coupled to the output of the first filter circuitry, the second input of the buffer circuitry coupled to the output of the second filter circuitry, the output of the buffer circuitry coupled to the control input of the second multiplexer circuitry.

17. An apparatus comprising:
multiplexer circuitry having a first output and a second output;
first delay circuitry having an input and an output, the input of the first delay circuitry coupled to the first output of the multiplexer circuitry, the first delay circuitry configured to delay signals by a filter delay, the filter delay based on a number of filter circuitry, a notch frequency, and an oversampling rate;
second delay circuitry having an input and an output, the input of the second delay circuitry coupled to the second output of the multiplexer circuitry, the second delay circuitry configured to delay signals by the filter delay;
first filter circuitry having an input coupled to the output of the first delay circuitry; and
second filter circuitry having an input coupled to the output of the second delay circuitry.

18. The apparatus of claim 17, wherein the multiplexer circuitry configured to cycle between the first filter circuitry and the second filter circuitry based on a conversion period, the conversion period being a line cycle period divided by the number of filter circuitry, the line cycle period being a period of a notch frequency.

19. The apparatus of claim 17, wherein the first filter circuitry configured to average a number of samples from the first delay circuitry across a line cycle period, the number of samples separated by a line cycle period, the line cycle period being a period of a notch frequency.

20. The apparatus of claim 17, wherein the first filter circuitry configured to attenuate signals at a notch frequency.
